(19) United States
(12) Patent Application Publication
(10) Pub. No.: US 2022/0406943 A1
(43) Pub. Date: Dec. 22, 2022

(54) SEMICONDUCTOR DEVICE AND CRYSTAL GROWTH METHOD

(71) Applicant: FLOSFIA INC., Kyoto (JP)

(72) Inventor: Katsuaki KAWARA, Kyoto (JP)

(21) Appl. No.: 17/890,477

(22) Filed: Aug. 18, 2022

Related U.S. Application Data
(63) Continuation-in-part of application No. PCT/JP2021/005763, filed on Feb. 16, 2021.

(30) Foreign Application Priority Data
Feb. 18, 2020 (JP) 2020-025273
Feb. 18, 2020 (JP) 2020-025274
Feb. 18, 2020 (JP) 2020-025275

(51) Int. Cl. H01L 29/786; H01L 29/24; H01L 23/367; H01L 23/42; H01L 21/02; C30B 25/02; C30B 29/16

(52) U.S. Cl. CPC H01L 29/7869; H01L 29/24; H01L 23/367; H01L 23/42; H01L 21/0259; H01L 21/02565; C30B 25/02; C30B 29/16; H02M 7/53871

(57) ABSTRACT

Provided is a semiconductor device, including at least: a semiconductor layer; and a gate electrode that is arranged directly or via another layer on the semiconductor layer, the semiconductor device being configured in such a manner as to cause a current to flow in the semiconductor layer at least in a first direction that is along with an interface between the semiconductor layer and the gate electrode, the semiconductor layer having a corundum structure, a direction of an m-axis in the semiconductor layer being the first direction.

### CROSS REFERENCE TO RELATED APPLICATION

This application is a continuation-in-part application of International Patent Application No. PCT/JP2021/005763 (Filed on Feb. 16, 2021), which claims the benefit of priority from Japanese Patent Application No. 2020-025273 (filed on Feb. 18, 2020), No. 2020-025274 (filed on Feb. 18, 2020), and No. 2020-025275 (filed on Feb. 18, 2020).

The entire contents of the above applications, which the present application is based on, are incorporated herein by reference.

### FIELD OF THE INVENTION

The present disclosure relates to a semiconductor device suitable for use in a power device and the like. The present disclosure also relates to a crystal growth method capable of obtaining crystal suitable for use in a power device and the like.

### DESCRIPTION OF THE RELATED ART

Hitherto, there has been a problem in that a crack and a lattice defect occur when crystal growth is performed on a heterogeneous substrate. With regard to this problem, the alignment of the lattice constant and the thermal expansion coefficient between a substrate and a film, for example, has been examined. A film formation approach such as ELO has also been examined when such misalignment occurs.

A method of forming a buffer layer on the heterogeneous substrate and causing the crystal growth of a zinc oxide semiconductor layer on the buffer layer has been known. A method of forming a nanodot mask on the heterogeneous substrate and then forming a monocrystalline semiconductor material layer has been known. An approach of causing the crystal growth of GaN on sapphire via a nano-column of GaN has been known. An approach of reducing defects such as pits by causing the crystal growth of GaN on Si(111) with use of a periodic SiN interlayer has been known.

However, in all of the technologies, it has been difficult to obtain a high-quality epitaxial film due to the film formation speed being wrong, a crack, a dislocation, a warp, and the like being generated in the substrate, or a dislocation, a crack, and the like occurring in the epitaxial film, for example. There also has been trouble regarding the diameter increase of the substrate and the thickening of the epitaxial film.

A semiconductor device using gallium oxide (Ga₂O₃) having a great band gap has been gathering attention as a next-generation switching element capable of realizing high voltage resistance, low loss, and high thermal resistance and has been expected to be applied to a power semiconductor device such as an inverter. Application as a light receiving/emitting apparatus such as an LED and a sensor has also been expected due to the wide band gap. It becomes possible to perform band gap control by obtaining mixed crystal formed by mixing each of indium or aluminum or a combination of indium and aluminum with the gallium oxide, and the gallium oxide configures an extremely attractive family of material as an InAlGaO-based semiconductor. Here, InAlGaO-based semiconductors indicate In_{X}Al_{Y}Ga_{Z}O₃ (0≤X≤2, 0≤Y≤2, 0≤Z≤2, X+Y+Z=1.5 to 2.5) and may be regarded as a family of power device including gallium oxide.

However, gallium oxide has β-gallia structure in the most stabilized phase. Therefore, it is difficult to form a crystal film having a corundum structure unless a special film formation method is used, and there also still has been many problems regarding the crystal quality and the like. With respect to the above, several examinations have currently been made regarding the film formation of a crystalline semiconductor having a corundum structure.

### SUMMARY OF THE INVENTION

According to an example of the present disclosure, there is provided a semiconductor device, including at least: a semiconductor layer; and a gate electrode that is arranged directly or via another layer on the semiconductor layer, the semiconductor device being configured in such a manner as to cause a current to flow in the semiconductor layer at least in a first direction that is along with an interface between the semiconductor layer and the gate electrode, the semiconductor layer having a corundum structure, a direction of an m-axis in the semiconductor layer being the first direction.

According to an example of the present disclosure, there is provided a semiconductor device, including at least: a semiconductor layer having a corundum structure; a first electrode disposed on a first plane side of the semiconductor layer; and a second electrode disposed on a second plane side that is a side opposite from the first plane side, the first plane being an m-plane, the second electrode being longer than the first electrode in at least a first direction, and the first direction being a c-axis direction of the semiconductor layer.

Thus, a semiconductor device of the present disclosure is excellent in the semiconductor property, in particular, the electrical property.

According to an example of the present disclosure, there is provided a crystal growth method, including causing crystal growth of crystal having a corundum structure on a c-plane of a crystal substrate for crystal growth having a corundum structure, the crystal substrate having an uneven portion provided thereon such that a dislocation in accordance with the crystal growth further extends in an m-axis direction than in an a-axis direction.

Thus, in a method of the present disclosure, it becomes possible to industrially form the crystal, the crystal film, and/or the semiconductor layer in which dislocation is reduced in an advantageous manner.

### BRIEF DESCRIPTION OF THE DRAWINGS

FIG. 1 illustrates a schematic configuration view of a film formation apparatus as one example of a film formation apparatus suitably used in an embodiment of the present disclosure.

FIG. 2 illustrates a schematic configuration view of a film formation apparatus (mist CVD) of an aspect different from that of FIG. 1 suitably used in the embodiment of the present disclosure.

FIG. 3 is a diagram schematically illustrating one suitable example of a power source system.

FIG. 4 is a diagram schematically illustrating one suitable example of a system apparatus.

FIG. 5 is a diagram schematically illustrating one suitable example of a power source circuit diagram of a power source apparatus.

FIG. 6 is a view schematically illustrating one example of a metal-oxide-semiconductor field-effect transistor (MOSFET) as one aspect of a semiconductor device in the embodiment of the present disclosure.

FIG. 7 illustrates a part of a schematic top view as one aspect of the semiconductor device in the embodiment of the present disclosure.

FIG. 8 illustrates a schematic partial cross-sectional view as one aspect of the semiconductor device in the embodiment of the present disclosure, the schematic partial cross-sectional view being an outline view as one example of a cross-section taken along line A-A of FIG. 7, for example.

FIG. 9 illustrates a partial cross-sectional view illustrating a specific example as one aspect of the semiconductor device in the embodiment of the present disclosure, the partial cross-sectional view being an outline view as one example of a cross-section taken along line A-A of FIG. 7, for example.

FIG. 10 illustrates a view schematically illustrating one suitable example of a Schottky barrier diode (SBD) using a rectangular semiconductor layer, the view being a cross-sectional view in the longitudinal direction.

FIG. 11 illustrates a view schematically illustrating one suitable example of a metal-oxide-semiconductor field-effect transistor (MOSFET) using a rectangular semiconductor layer, the view being a cross-sectional view in the longitudinal direction.

FIG. 12 illustrates a view schematically illustrating one suitable example of an insulated gate bipolar transistor (IGBT) using a rectangular semiconductor layer, the view being a cross-sectional view in the longitudinal direction.

FIG. 13 illustrates a view schematically illustrating one suitable example of a junction barrier Schottky diode (JBS) using a rectangular semiconductor layer, the view being a cross-sectional view in the longitudinal direction.

FIG. 14 illustrates a view schematically illustrating one suitable example of a junction barrier Schottky diode (JBS) using a rectangular semiconductor layer, the view being a cross-sectional view in the longitudinal direction.

FIG. 15 is a view schematically illustrating one suitable example of a power card.

FIG. 16 is a view illustrating a result of Example 1.

FIG. 17 is a partially enlarged view of a central portion of FIG. 16.

FIG. 18 is a view describing a hydride vapor phase epitaxy (HVPE) apparatus suitably used in the embodiment of the present disclosure.

FIG. 19 is a view schematically illustrating a surface of an uneven portion formed on a surface of a substrate suitably used in one embodiment of the present disclosure.

FIG. 20 is a schematic view schematically illustrating the surface of the uneven portion formed on the surface of the substrate suitably used in one embodiment of the present disclosure.

FIG. 21 is a top perspective view schematically illustrating the surface of the uneven portion formed on the surface of the substrate suitably used in one embodiment of the present disclosure.

FIG. 22 illustrates an explanatory view of a protruding portion of the uneven portion of the substrate illustrated in FIG. 21, the explanatory view being a partial cross-sectional view cut across the uneven portion of the substrate.

FIG. 23 illustrates an explanatory view of a depressed portion of the uneven portion of the substrate illustrated in FIG. 21, the explanatory view being a partial cross-sectional view cut across the uneven portion of the substrate.

FIG. 24-a is a perspective view schematically illustrating a substrate and a mask used in Example 2 of the present disclosure.

FIG. 24-b is a plan view of FIG. 24-a, the plan view being an outline view illustrating that the centers of a plurality of openings that pass through the mask from an upper plane to a lower plane of the mask are positioned in vertices of a triangular lattice.

FIG. 24-c is an AFM (atomic force microscopy) image indicating a result of Example 2.

FIG. 24-d is a schematic explanatory view illustrating the positions in which the openings in the mask are provided in planar view on the AFM image illustrated in FIG. 24-c.

FIG. 25-a is a perspective view schematically illustrating a substrate and a mask used in Example 3 of the present disclosure.

FIG. 25-b is a plan view of FIG. 25-a, the plan view being an outline view illustrating that the centers of a plurality of openings that pass through the mask from an upper plane to a lower plane of the mask are positioned in vertices of a triangular lattice.

FIG. 25-c is an AFM (atomic force microscopy) image indicating a result of Example 2.

FIG. 25-d is a schematic explanatory view showing the positions in which the openings are provided in the mask in planar view on the AFM image shown in FIG. 24-c by dotted lines.

### DETAILED DESCRIPTION

The inventors of the present disclosure found out that the electrical property has anisotropy in the relationship between a crystal axis of gallium oxide crystal having a corundum structure and the direction in which the current flows, and have succeeded in inventing a semiconductor device including at least: a semiconductor layer; and a first electrode and a second electrode each disposed on a first plane side of the semiconductor layer. In the semiconductor device, current flows in a first direction from the first electrode toward the second electrode in the semiconductor layer, the semiconductor layer has a corundum structure, and a direction of an m-axis of the semiconductor layer is parallel to the first direction.

The inventors of the present disclosure found out that the electrical property has anisotropy in the relationship between the crystal axis of the gallium oxide crystal having a corundum structure and the direction in which the current flows, and have succeeded in inventing a semiconductor device including at least: a semiconductor layer having a corundum structure; a first electrode disposed on a first plane side of the semiconductor layer; and a second electrode disposed on a second plane side that is a side opposite from the first plane side. In the semiconductor device, the second electrode is longer than the first electrode in at least a first direction, the first plane is an m-plane, and the first direction is a c-axis direction of the semiconductor layer.

The inventors of the present disclosure found a crystal growth method including causing crystal growth of crystal having a corundum structure on a c-plane of a crystal substrate for crystal growth having a corundum structure, the crystal substrate having an uneven portion provided thereon such that a dislocation in accordance with the crystal growth further extends in an m-axis direction than in an a-axis direction. The inventors of the present disclosure have found that such crystal growth method is capable of reducing dislocation by utilizing the anisotropy of the dislocation.

Embodiments of the present disclosure will be described below with reference to the accompanying drawings. In the following description, the same parts and components are designated by the same reference numerals. The present embodiment includes, for example, the following disclosures.

### [Structure 1]

A semiconductor device, including at least: a semiconductor layer; and a gate electrode that is arranged directly or via another layer on the semiconductor layer, the semiconductor device being configured in such a manner as to cause a current to flow in the semiconductor layer at least in a first direction that is along with an interface between the semiconductor layer and the gate electrode, the semiconductor layer having a corundum structure, a direction of an m-axis in the semiconductor layer being the first direction.

### [Structure 2]

A semiconductor device, including at least: a semiconductor layer having a corundum structure; a first electrode disposed on a first plane side of the semiconductor layer; and a second electrode disposed on a second plane side that is a side opposite from the first plane side, the first plane being an m-plane, the second electrode being longer than the first electrode in at least a first direction, and the first direction being a c-axis direction of the semiconductor layer.

### [Structure 3]

The semiconductor device according to [Structure 1] or [Structure 2], wherein the semiconductor layer includes a metal oxide containing at least one metal selected from gallium, indium, rhodium, iridium, and aluminum.

### [Structure 4]

The semiconductor device according to [Structure 1] or [Structure 2], wherein a major component of the semiconductor layer is metal oxide containing at least gallium.

### [Structure 5]

The semiconductor device according to [Structure 1], wherein the semiconductor layer has a carrier concentration of 1×10¹⁹/cm³ or less.

### [Structure 6]

The semiconductor device according to [Structure 2], wherein the first plane is a c-plane.

### [Structure 7]

The semiconductor device according to [Structure 1], wherein the semiconductor layer includes at least a dislocation that extends in the first direction.

### [Structure 8]

The semiconductor device according to [Structure 1], wherein the semiconductor layer does not substantially include a dislocation that extends in a direction that is vertical or substantially vertical to the first direction.

### [Structure 9]

The semiconductor device according to any one of [Structure 1] to [Structure 8], wherein the semiconductor device is a power device.

### [Structure 10]

The semiconductor device according to [Structure 9], wherein the semiconductor device is a power module, an inverter, or a converter.

### [Structure 11]

The semiconductor device according to [Structure 9], wherein the semiconductor device is a power card.

### [Structure 12]

The semiconductor device according to [Structure 10], further including a cooler and an insulation member, wherein the cooler is provided on each of both sides of the semiconductor layer via at least the insulation member.

### [Structure 13]

The semiconductor device according to [Structure 11], wherein: a heat release layer is provided on each of both sides of the semiconductor layer; and the cooler is provided on an outer side of the heat release layer via at least the insulation member.

### [Structure 14]

A semiconductor system, including a semiconductor device, wherein the semiconductor device is the semiconductor device according to any one of [Structure 1] to [Structure 13].

### [Structure 15]

A crystal growth method, including causing crystal growth of crystal having a corundum structure on a c-plane of a crystal substrate for crystal growth having a corundum structure, the crystal substrate having an uneven portion provided thereon such that a dislocation in accordance with the crystal growth further extends in an m-axis direction than in an a-axis direction.

### [Structure 16]

The method according to any one of [Structure 15], wherein the crystal contains metal oxide containing at least one metal selected from gallium, indium, rhodium, iridium, and aluminum.

### [Structure 17]

The method according to [Structure 15] or [Structure 16], wherein a major component of the crystal is metal oxide containing at least gallium.

### [Structure 18]

The method according to any one of [Structure 15] to [Structure 17], wherein the uneven portion includes at least two or more of inclined planes that are m-planes adjacent to each other.

### [Structure 19]

The method according to any one of [Structure 15] to [Structure 18], wherein the uneven portion includes at least two or more of inclined planes that are m-planes facing each other.

A semiconductor device in one embodiment of the present disclosure includes at least: a semiconductor layer; and a first electrode and a second electrode each disposed on a first plane side of the semiconductor layer. In the semiconductor device, current flows in a first direction from the first electrode toward the second electrode in the semiconductor layer, the semiconductor layer has a corundum structure, and a direction of an m-axis of the semiconductor layer is parallel to the first direction.

A semiconductor device in another embodiment of the present disclosure includes at least: a semiconductor layer having a corundum structure; a first electrode disposed on a first plane side of the semiconductor layer; and a second electrode disposed on a second plane side that is a side opposite from the first plane side. In the semiconductor device, the first plane is an m-plane, the second electrode is longer than the first electrode in at least a first direction, and the first direction is a c-axis direction of the semiconductor layer.

In the embodiment of the present disclosure, the semiconductor layer contains metal oxide containing at least one metal selected from gallium, indium, rhodium, iridium, and aluminum. In the embodiment of the present disclosure, it becomes possible to exhibit a semiconductor property that is better in terms of high voltage resistance and the like when the major component of the semiconductor layer is metal oxide containing at least gallium. The “major component” means that the metal oxide is contained by 50% or more, preferably 70% or more, and more preferably 90% or more at atomic ratio with respect to all components in the semiconductor layer and may be 100% depending on the embodiment. It is preferred that the metal oxide contain at least gallium and further contain indium, rhodium, or iridium. It is also preferred that the metal oxide contain at least gallium and further contain indium or/and aluminum. It is more preferred that the metal oxide contain at least gallium because it becomes possible to cause the property as a power device such as a switching property to be better. In the embodiment of the present disclosure, it is preferred that the first plane be a c-plane because it becomes possible to cause the electrical property to be better.

One example of an embodiment of a crystal growth method of the present disclosure is a crystal growth method including causing crystal growth of crystal having a corundum structure on a c-plane of a crystal substrate for crystal growth having a corundum structure, the crystal substrate having an uneven portion provided thereon such that a dislocation in accordance with the crystal growth further extends in an m-axis direction than in an a-axis direction. One example of the embodiment of the present disclosure is a crystal growth method that is a method of causing crystal growth of crystal having a corundum structure with use of a crystal substrate for crystal growth. In the crystal growth method, an uneven portion that causes a dislocation that extends in an m-axis direction of the crystal to move from a direction of the crystal growth is provided on a crystal-growth-plane side of the crystal substrate. In the embodiment of the present disclosure, it is preferred that a protruding portion of the uneven portion be a mask. It is preferred that the mask be a mask containing TiO₂. It is preferred that a principal plane of the crystal substrate on which the uneven portion is provided be a c-plane. As one example of the embodiment, it is preferred that the crystal contain metal oxide containing at least one metal selected from gallium, indium, rhodium, chromium, iridium, and aluminum, and it is more preferred that the crystal contain metal oxide containing at least one metal selected from gallium, indium, rhodium, iridium, and aluminum. In the embodiment of the present disclosure, it is more preferred that the major component of the crystal be metal oxide containing at least gallium. It is preferred that the crystal growth be performed by at least one method selected from CVD, MOCVD, MOVPE, mist CVD, mist epitaxy, MBE, HVPE, pulsed growth, and ALD. As another example of the embodiment of the present disclosure, it is also preferred that the uneven portion include at least two or more inclined planes that are m-planes adjacent to each other. In the embodiment, it is preferred that the uneven portion include at least two or more of inclined planes that are m-planes facing each other. By causing crystal growth of the crystal having a corundum structure such that the direction of the crystal growth includes the c-axis direction, the a-axis direction, and the m-axis direction, it becomes possible to easily obtain crystal in which dislocation is reduced in the a-axis direction.

The crystal growth method in a preferred embodiment of the present disclosure is advantageous in obtaining crystal with excellent semiconductor property, and the crystal is suitably usable as a semiconductor layer in a semiconductor device.

It is preferred that the semiconductor layer be a crystalline oxide semiconductor layer and include a crystalline oxide semiconductor. It is preferred that the crystalline oxide semiconductor contain the metal oxide and contain at least gallium as described above, and it is more preferred that the crystalline oxide semiconductor contain gallium oxide and mixed crystal thereof as the major component. The crystal structure and the like of the crystalline oxide semiconductor are not particularly limited. However, in the present disclosure, it is preferred that the crystalline oxide semiconductor contain metal oxide having a corundum structure as the major component. The metal oxide is not particularly limited, but preferably contains at least one type or two or more types of metal from period 4 to period 6 in the periodic table, more preferably contains at least gallium, indium, rhodium, or iridium, and most preferably contains gallium. In the present disclosure, it is also preferred that the metal oxide contain gallium, indium, or/and aluminum. The metal oxide containing gallium includes α-Ga₂O₃ or mixed crystal thereof, for example. The semiconductor layer containing such preferred metal oxide as the major component may have better crystal property and heat release property and may also have even better semiconductor property. For example, when the metal oxide is α-Ga₂O₃, the atomic ratio of gallium contained in the semiconductor layer only needs to be as follows. Specifically, α-Ga₂O₃ only needs to be contained in the semiconductor layer at a rate of 50% or more with respect to all metal components of the semiconductor layer. In the present disclosure, the atomic ratio of gallium in the metal components of the semiconductor layer is preferably 70% or more and more preferably 80% or more with respect to all of the metal components in the semiconductor layer. The semiconductor layer may be monocrystal or may be polycrystal. The semiconductor layer is normally in a film form but is not particularly limited unless it interferes with the present disclosure and may be in a plate form or a sheet form.

The semiconductor layer may also contain a dopant. The dopant is not particularly limited unless it interferes with the present disclosure. The dopant may be an n-type dopant or a p-type dopant. Examples of the n-dopant include tin, germanium, silicon, titanium, zirconium, vanadium, or niobium. The carrier concentration may be set, as appropriate. Specifically, the carrier concentration may be from about 1×10¹⁶/cm³ to about 1×10²²/cm³, for example, or the carrier concentration may be a low concentration of about 1×10¹⁷/cm³ or less, for example. As one example of the embodiment, for example, the carrier concentration of the semiconductor layer may be contained by a high concentration of about 1×10²⁰/cm³ or more. However, in the embodiment of the present disclosure, it becomes possible to cause the anisotropy to be more effective and the semiconductor property to be more satisfactory when the carrier concentration of the semiconductor layer becomes lower. Therefore, the carrier concentration is preferably 1×10¹⁹/cm³ or less, more preferably 5×10¹⁸/cm³ or less, and most preferably 1×10¹⁸/cm³ or less, for example.

The semiconductor layer is obtainable by a suitable film formation method as follows, for example. For example, the semiconductor layer is obtainable by producing a semiconductor device by forming the semiconductor layer by causing epitaxial crystal growth by mist CVD or mist epitaxy such that the current flows in the first direction from the first electrode toward the second electrode with use of a crystal substrate in which a second edge is set to be shorter than a first edge. The first direction is the m-axis direction.

### <Crystal Substrate>

The crystal substrate is not particularly limited unless it interferes with the present disclosure and may be a well-known substrate. The crystal substrate may be an insulator substrate, a conductive substrate, or a semiconductor substrate. The crystal substrate may be a monocrystalline substrate or a polycrystalline substrate. Examples of the crystal substrate include a substrate containing a crystal substance having a corundum structure as the major component. The expression of “major component” means that the crystal substance is contained by 50% or more, preferably 70% or more, and more preferably 90% or more at composition ratio in the substrate. Examples of the crystal substrate having a corundum structure include a sapphire substrate, an α-type gallium oxide substrate, and an α-type mixed crystal substrate which contains Ga₂O₃ and Al₂O₃ and in which Al₂O₃ is more than 0 wt % and equal to or less than 60 wt %.

In the present disclosure, it is preferred that the crystal substrate be a sapphire substrate. Examples of the sapphire substrate include a c-plane sapphire substrate, an m-plane sapphire substrate, an a-plane sapphire substrate, and an r-plane sapphire substrate. However, in the embodiment of the present disclosure, it is preferred that the c-plane sapphire substrate and a c-plane α-Ga₂O₃ substrate be used. The sapphire substrate may have an off-angle. The off-angle is not particularly limited and is 0.01 degrees or more, for example, but is preferably 0.2 degrees or more and more preferably from 0.2 degrees to 12 degrees. It is also preferred that the sapphire substrate be a c-plane sapphire substrate having an off-angle of 0.2 degrees or more.

The thickness of the crystal substrate is not particularly limited but is normally from 10 μm to 20 mm and is more preferably from 10 μm to 1000 μm.

In the present disclosure, the direction of the crystal growth and the like may be controlled with use of an ELO mask such that the second edge easily becomes shorter than the first edge, the linear thermal expansion coefficient of a first crystal axial direction easily becomes smaller than the linear thermal expansion coefficient of a second crystal axial direction, a first edge direction easily becomes parallel or substantially parallel to the first crystal axial direction, and a second edge direction easily becomes parallel or substantially parallel to the second crystal axial direction in the semiconductor layer.

Examples of the suitable shape of the crystal substrate include polygonal shapes such as a triangular shape, a quadrilateral shape (for example, a rectangular shape or a trapezoidal shape), a pentagonal shape, or a hexagonal shape, a U-shape, an inverted U-shape, an L-shape, or a squared U-shape.

In the present disclosure, other layers such as a buffer layer and a stress alleviation layer may be provided on the crystal substrate. Examples of the buffer layer include a layer formed by metal oxide having the same crystal structure as the crystal structure of the crystal substrate or the semiconductor layer. Examples of the stress alleviation layer include an ELO mask layer.

A preferred aspect of the crystal substrate suitably used in the present disclosure is described below with reference to the drawings.

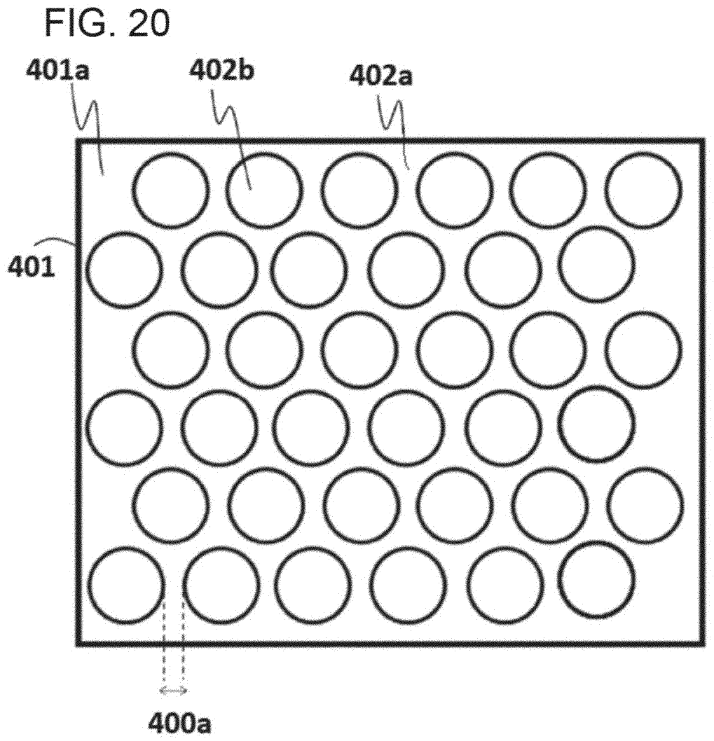

FIG. 19 illustrates one aspect of the uneven portion provided on a crystal growth plane of the crystal substrate in the present disclosure. The uneven portion in FIG. 19 is configured by a crystal substrate 401 and a mask layer 404. FIG. 20 illustrates the surface of the uneven portion illustrated in FIG. 19 seen from the zenith direction. As is seen from FIG. 19 and FIG. 20, the mask layer 404 is formed on the crystal growth plane of the crystal substrate 401 as a protruding portion 402a, and dot-like depressed portions 402b indicate openings provided in the mask layer. The dot-like depressed portions 402b of the mask layer 404 are openings. The crystal substrate 401 is exposed from the openings. The dot-like depressed portions 402b are formed such that centers thereof are positioned in vertices of a triangular lattice. The circles of the dots are provided at an interval of a certain pitch 400a. The pitch 400a is not particularly limited but is preferably from 1 μm to 1 mm and more preferably from 5 μm to 300 μm in the present disclosure. The pitch 400a is a distance between end portions of the circles of the dots that are adjacent to each other. The mask layer 404 is formable by performing film formation of a constituent material of the mask layer 404 and then processing the film into a predetermined shape with use of well-known means such as photolithography. Examples of the constituent material of the mask layer 404 include oxides, nitrides, or carbides of Si, Ge, Ti, Zr, Hf, Ta, Sn, Al, and the like, carbon, diamond, metal, or a mixture of the above. In the present disclosure, the mask layer 404 preferably contains metal oxide of transition metal, preferably contains metal in group 4 of the periodic table, and most preferably contains titanium oxide. By causing the constituent material of the mask layer 404 to be a preferable material as above, it becomes possible to cause the crystalline nature of a crystalline oxide layer to be better. Film formation means for the mask layer 404 is not particularly limited and may be well-known means. Examples of the film formation means for the mask layer 404 include vacuum deposition, CVD, or spattering. In the present disclosure, it is preferred that the spattering be used when the mask layer 404 contains titanium oxide because polycrystalline oxide is formable on the mask layer 404 in a more suitable manner. Reactive sputtering is more preferably used, and reactive sputtering while O₂ gas is being supplied is most preferably used.

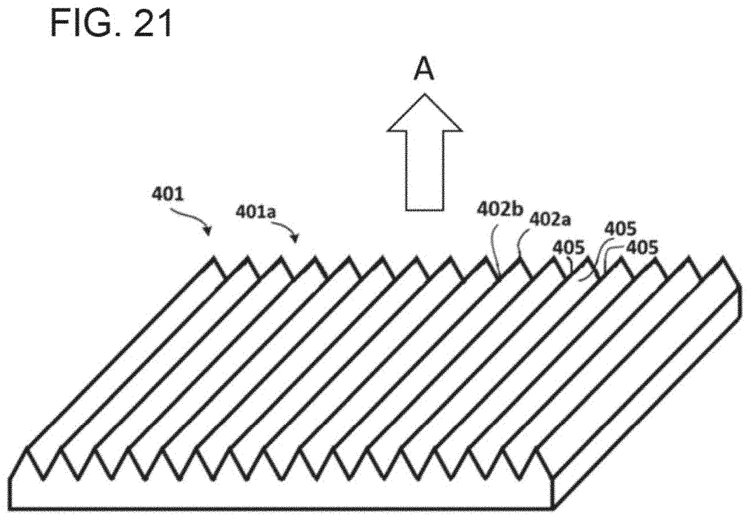

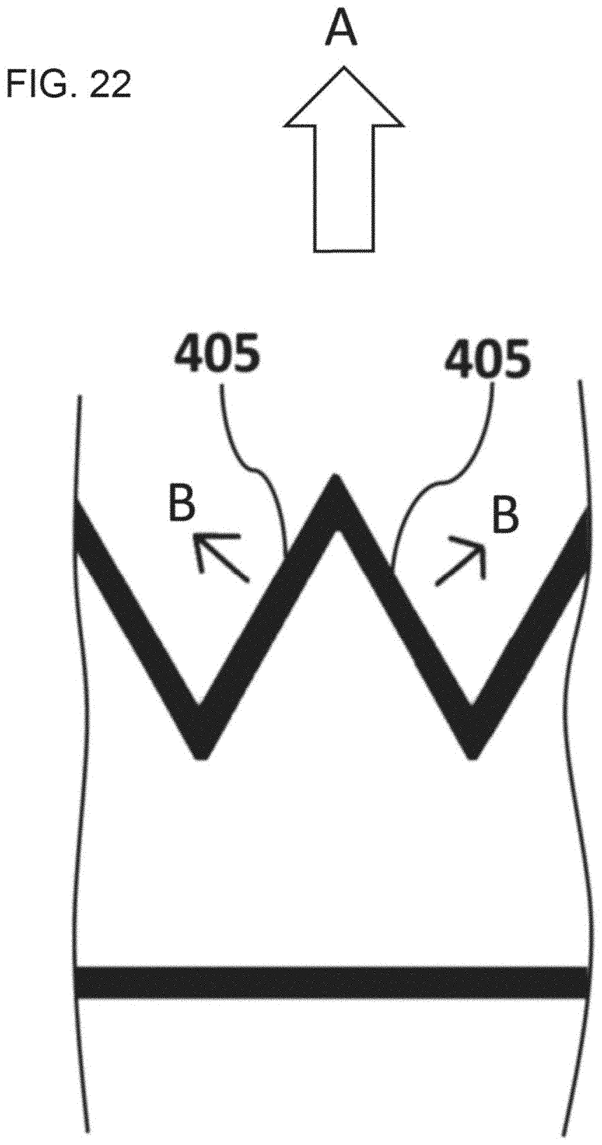

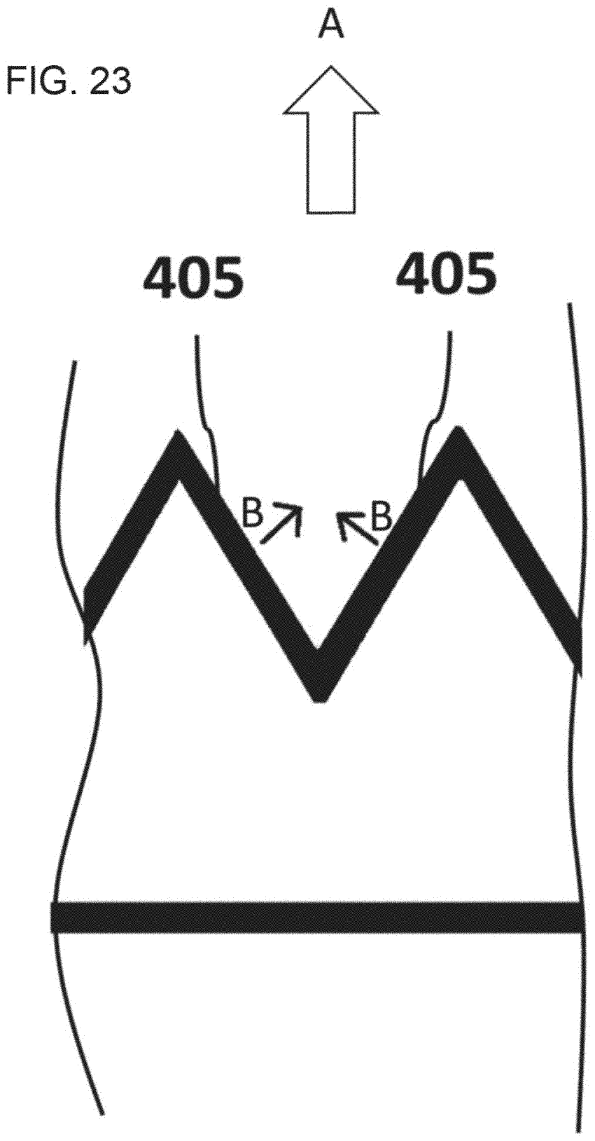

FIG. 21 is a top perspective view schematically illustrating the surface of an uneven portion formed on the surface of the substrate used in one embodiment of the crystal growth method of the present disclosure. FIG. 22 illustrates an explanatory view of the protruding portion of the uneven portion of the substrate illustrated in FIG. 21, the explanatory view being a partial cross-sectional view cut across the uneven portion of the substrate. In the present embodiment, the substrate 401 may be a sapphire substrate and may be a patterned sapphire substrate (PSS) having an uneven portion disposed to be parallel to a surface 401a of the substrate 401. Unlike the uneven portion illustrated in FIGS. 19 and 20, the uneven portion only needs to include at least one or more of inclined planes 405 adjacent to each other and/or the inclined planes 405 facing each other in the present embodiment, and the inclined plane 405 is preferably an m-plane in the present embodiment. In the substrate illustrated in FIG. 21, the cross-sectional shape of the protruding portion 402a and/or the depressed portion 402b is a triangular shape and the size of the vertex angle is set to 60 degrees. By causing the cross-sectional plane of the protruding portion 402a to be a ridge-like form having a triangular shape as illustrated in FIG. 21, it becomes possible to extend a dislocation in accordance with the crystal growth in a direction (m-axis direction) perpendicular to the inclined plane 405 as indicated by arrows B in FIG. 22 and avoid the extension of the dislocation in accordance with the crystal growth in the crystal growth direction as indicated by arrow A. In the depressed portion 402b of the uneven portion of the substrate, the dislocation density and the dislocation region extending in the a-axis direction are reducible by causing the dislocations in accordance with the crystal growth to extend in directions (m-axis directions) perpendicular to the inclined planes 405 of the depressed portion 402b facing each other as indicated by arrows B in FIG. 23, causing the dislocations to approach each other, and prompting annihilation of the dislocations. As above, wide-range crystal in which dislocation is reduced is obtainable in the crystal growth direction.

Means for epitaxial crystal growth is not particularly limited unless it interferes with the present disclosure and may be well-known means. Examples of the epitaxial crystal growth means include CVD, MOCVD, MOVPE, mist CVD, mist epitaxy, MBE, HVPE, pulsed growth, or ALD. In the present disclosure, it is preferred that the epitaxial crystal growth means be mist CVD or mist epitaxy.

The mist CVD or the mist epitaxy is performed by atomizing a raw material solution containing metal (atomization process), causing droplets to float and carrying the obtained atomized droplets to the vicinity of the crystal substrate by carrier gas (carrying process), and then causing thermal reaction of the atomized droplets (film formation process).

### (Raw Material Solution)

The raw material solution is not particularly limited as long as metal is contained as the raw material for film formation and atomization is possible and may contain an inorganic material or an organic material. The metal may be elemental metal or a metal compound and is not particularly limited unless it interferes with the present disclosure. However, examples of the metal include one type or two or more types of metal selected from gallium (Ga), iridium (Ir), indium (In), rhodium (Rh), aluminum (Al), gold (Au), silver (Ag), platinum (Pt), copper (Cu), iron (Fe), manganese (Mn), nickel (Ni), palladium (Pd), cobalt (Co), ruthenium (Ru), chromium (Cr), molybdenum (Mo), tungsten (W), tantalum (Ta), zinc (Zn), lead (Pb), rhenium (Re), titanium (Ti), tin (Sn), magnesium (Mg), calcium (Ca), and zirconium (Zr). However, in the present disclosure, the metal preferably contains at least one type or two or more types of metal in period 4 to period 6 of the periodic table, and more preferably contains at least gallium, indium, rhodium, or iridium. In the present disclosure, it is also preferred that the metal contain gallium, indium, or/and aluminum. By using the preferred metal as above, it becomes possible to perform film formation of the semiconductor layer usable in the semiconductor device and the like in a more suitable manner.

In the present disclosure, as the raw material solution, a raw material solution obtained by causing the metal to be dissolved or dispersed in an organic solvent or water in a form of a complex or salt is suitably usable. Examples of the form of a complex include an acetylacetonato complex, a carbonyl complex, an ammine complex, and a hydride complex. Examples of the form of salt include organometallic salt (for example, metal acetate salt, metal oxalate salt, and metal citrate salt), metal sulfate salt, metal nitrate salt, metal phosphate salt, and metal halide salt (for example, metal chloride salt, metal bromide salt, and metal iodine salt).

The solvent of the raw material solution is not particularly limited unless it interferes with the present disclosure and may be an inorganic solvent such as water, an organic solvent such as alcohol, or a mixed solvent of an inorganic solvent and an organic solvent. In the present disclosure, it is preferred that the solvent contain water.

In the raw material solution, additives such as hydrohalic acid and oxidant may be mixed. Examples of the hydrohalic acid include hydrobromic acid, hydrochloric acid, and hydriodic acid. Examples of the oxidant include peroxide such as hydrogen peroxide (H₂O₂), sodium peroxide (Na₂O₂), barium peroxide (BaO₂), benzoyl peroxide (C₆H₅CO)₂O₂, and organic peroxide such as hypochlorous acid (HClO), perchloric acid, nitric acid, ozone water, peracetic acid, and nitrobenzene.

A dopant may be contained in the raw material solution. The dopant is not particularly limited unless it interferes with the present disclosure. Examples of the dopant include an n-type dopant or a p-type dopant of tin, germanium, silicon, titanium, zirconium, vanadium, niobium, or the like. The concentration of the dopant may be from about 1×10¹⁶/cm³ to about 1×10²²/cm³, for example, or concentration of the dopant may be a low concentration of about 1×10¹⁷/cm³ or less, for example. According to the present disclosure, the dopant may be contained at a high concentration of about 1×10²⁰/cm³ or more.

### (Atomization Process)

The atomization process adjusts a raw material solution containing metal, atomizes the raw material solution, causes droplets to float, and generates atomization droplets. The blending ratio of the metal is not particularly limited but is preferably from 0.0001 mol/L to 20 mol/L with respect to the entire raw material solution. The atomization means is not particularly limited as long as atomization of the raw material solution is possible, and the atomization means may be well-known atomization means, but is preferably atomization means using ultrasonic vibration in the present disclosure. It is more preferred that the mist used in the present disclosure float on air and be mist that is not sprayed like a spray, for example, but has zero initial velocity, floats on air, and is able to be carried as gas. The droplet size of the mist is not particularly limited but may be a droplet of about several millimeters, but is preferably 50 μm or less and more preferably from 1 μm to 10 μm.

### (Carrying Process)

In the carrying process, the atomization droplets are carried to the base by the carrier gas. The type of the carrier gas is not particularly limited unless it interferes with the present disclosure, and suitable examples thereof include oxygen, ozone, inert gas (for example, nitrogen and argon), or reducing gas (hydrogen gas, forming gas, and the like). The type of the carrier gas may be one type but also may be two or more types, and diluent gas (for example, ten-fold dilution gas) obtained by changing the carrier gas concentration, for example, may further be used as second carrier gas. The supplying place of the carrier gas does not necessarily need to be one place and may be two or more places. The flow rate of the carrier gas is not particularly limited but is preferably 1 LPM or less and more preferably from 0.1 LPM to 1 LPM.

### (Film Formation Process)

In the film formation process, a film is formed on the crystal substrate by causing the atomization droplets to react. The reaction is not particularly limited as long as a film is formed from the atomization droplets in the reaction but is preferably thermal reaction in the present disclosure. The thermal reaction only needs to be a reaction in which the atomization droplets react by heat, and the reaction conditions and the like are not particularly limited unless it interferes with the present disclosure. In the present process, the thermal reaction is normally performed at a temperature equal to or more than an evaporation temperature of the solvent of the raw material solution but is preferably a temperature that is not too high and is more preferably 650° C. or less. The thermal reaction may be performed under any atmosphere out of vacuum, non-oxygen atmosphere, reducing gas atmosphere, and oxygen atmosphere and may be performed under any condition out of atmospheric pressure, pressurization, and depressurization unless it interferes with the present disclosure. However, in the present disclosure, it is preferred that the thermal reaction be performed under atmospheric pressure because it becomes easier to calculate the evaporation temperature and it becomes possible to simplify equipment and the like, for example. The film thickness is settable by adjusting the amount of time of the film formation.

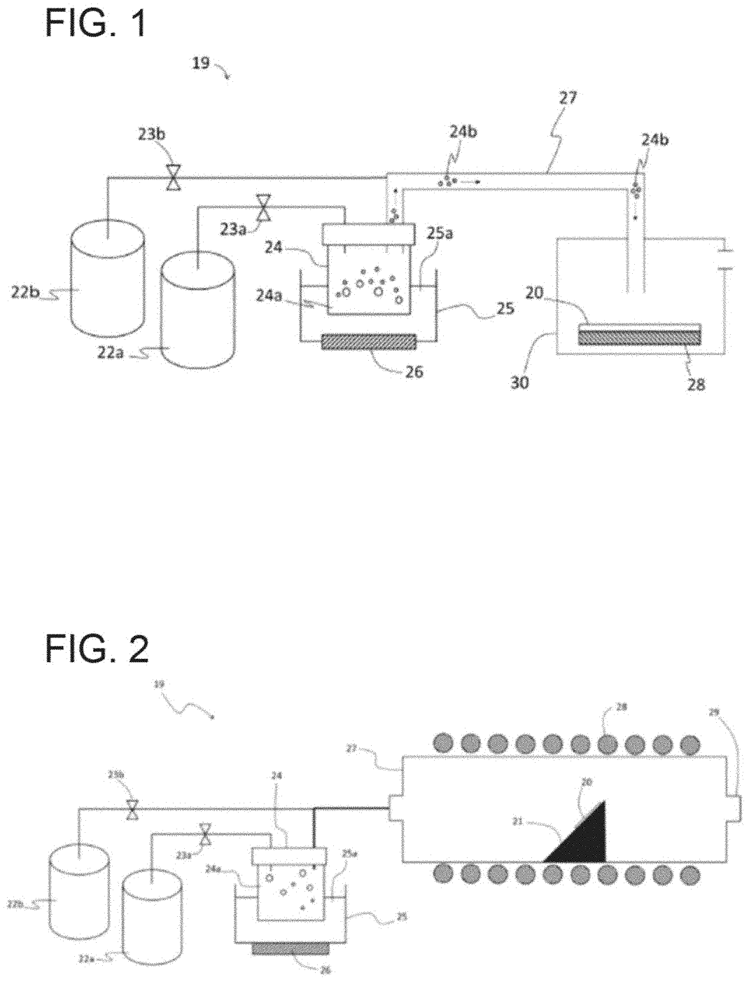

A film formation apparatus 19 suitably used in the present disclosure is described below with reference to the drawings. The film formation apparatus 19 in FIG. 1 includes a carrier gas source 22a that supplies carrier gas, a flow rate regulation valve 23a for regulating the flow rate of the carrier gas sent out from the carrier gas source 22a, a carrier gas (diluted) source 22b that supplies carrier gas (diluted), a flow rate regulation valve 23b for regulating the flow rate of the carrier gas (diluted) sent out from the carrier gas (diluted) source 22b, a mist generation source 24 in which a raw material solution 24a is accommodated, a container 25 in which water 25a is placed, an ultrasonic transducer 26 mounted on a bottom plane of the container 25, a film formation chamber 30, a supply pipe 27 made of quartz that forms connection from the mist generation source 24 to the film formation chamber 30, and a hotplate (heater) 28 installed in the film formation chamber 30. A substrate 20 is installed on the hotplate 28.

As illustrated in FIG. 1, the raw material solution 24a is accommodated in the mist generation source 24. Next, installation is performed on the hotplate 28 with use of the substrate 20, the hotplate 28 is actuated, and the temperature in the film formation chamber 30 is raised. Next, the carrier gas is supplied into the film formation chamber 30 from the carrier gas sources 22 (22a, 22b) by opening the flow rate regulation valves 23 (23a, 23b), and the atmosphere in the film formation chamber 30 is sufficiently replaced with the carrier gas. Then, the flow rate of the carrier gas and the flow rate of the carrier gas (diluted) are regulated. Next, the ultrasonic transducer 26 is vibrated, and the vibration is propagated to the raw material solution 24a through the water 25a. As a result, the raw material solution 24a is atomized and atomization droplets 24b are generated. The atomization droplets 24b are introduced into the film formation chamber 30 by the carrier gas and are carried to the substrate 20. Then, the atomization droplets 24b thermally react in the film formation chamber 30 under atmospheric pressure, and a film (semiconductor layer) is formed on the substrate 20.

It is also preferred that the mist CVD apparatus 19 be used as the film formation apparatus illustrated in FIG. 2. The mist CVD apparatus 19 in FIG. 2 includes a susceptor 21 on which the substrate 20 is placed, the carrier gas supplying means 22a for supplying carrier gas, the flow rate regulation valve 23a for regulating the flow rate of the carrier gas sent out from the carrier gas supplying means 22a, the carrier gas (diluted) supplying means 22b for supplying carrier gas (diluted), the flow rate regulation valve 23b for regulating the flow rate of the carrier gas sent out from the carrier gas (diluted) supplying means 22b, the mist generation source 24 in which the raw material solution 24a is accommodated, the container 25 in which the water 25a is placed, the ultrasonic transducer 26 mounted on the bottom plane of the container 25, the supply pipe 27 formed by a quartz pipe with an inner diameter of 40 mm, the heater 28 installed on a peripheral edge portion of the supply pipe 27, and an exhaust port 29 that discharges exhaust gas, droplets, and mist after the thermal reaction. The susceptor 21 is made of quartz, and a plane on which the substrate 20 is placed is inclined from the horizontal plane. By producing both of the susceptor 21 and the supply pipe 27 serving as the film formation chamber by quartz, a case where impurities derived from the apparatus are mixed into the film formed on the substrate 20 is suppressed. It is possible to treat the mist CVD apparatus 19 in a manner similar to the film formation apparatus 19.

With use of the suitable film formation apparatus, it becomes possible to form the semiconductor layer on the crystal growth plane of the crystal substrate in an easier manner. The semiconductor layer is normally formed by epitaxial crystal growth.

The semiconductor layer is suitable for use in a semiconductor device, in particular, a power device. Examples of the semiconductor device formed with use of the semiconductor layer include transistors such as a MIS and a HEMT, a TFT, a Schottky barrier diode using a metal-semiconductor junction, a JBS, a PN or PIN diode combined with another P layer, and a light receiving/emitting element. In the present disclosure, the semiconductor layer is obtainable by growing the crystalline oxide semiconductor and is usable in the semiconductor device as the semiconductor layer (film) by performing peeling from the crystal substrate, for example, if desired. It is also possible to use the semiconductor layer by disposing the semiconductor layer on a substrate of which thermal conductivity is higher than the crystal substrate, for example.

It is preferred that the semiconductor device be used in a horizontal element (horizontal device) in which an electrode is formed on one plane side of a semiconductor layer. Suitable examples of the semiconductor device include a Schottky barrier diode (SBD), a junction barrier Schottky diode (JBS), a metal-semiconductor field-effect transistor (MESFET), a high electron mobility transistor (HEMT), a metal-oxide-semiconductor field-effect transistor (MOSFET), a static induction transistor (SIT), a junction field-effect transistor (JFET), an insulated gate bipolar transistor (IGBT), or a light emitting diode (LED).

Suitable examples of the semiconductor device when the semiconductor layer in the embodiment of the present disclosure is applied to an n-type semiconductor layer (an n+-type semiconductor layer, an n− semiconductor layer, and the like) are described below with reference to the drawings, but the present disclosure is not limited to those examples.

As one example of the semiconductor device in the embodiment of the present disclosure, one example when the semiconductor device is a horizontal MOSFET is illustrated in FIG. 6. A semiconductor device 100 in the embodiment of the present disclosure at least has at least one semiconductor layer (for example, 131a), and a first electrode (for example, 135b) and a second electrode (for example, 135c) each disposed on a first plane side 100a of the semiconductor device 100, in other words, the first plane side of the semiconductor layer. Current flows in a first direction from the first electrode toward the second electrode in the semiconductor layer. The semiconductor layer has a corundum structure, and the direction of the m-axis of the semiconductor layer is parallel to the first direction. The expression of “the m-axis direction of the semiconductor layer is parallel to the first direction” means that the first direction from the first electrode toward the second electrode is parallel to the m-axis direction of the semiconductor layer and also includes a direction in an angle range within 5 degrees with respect to the m-axis direction. It is possible to cause the direction in which the current flows from the first electrode 135b to the second electrode 135c to be parallel to the m-axis direction. Therefore, it becomes possible to obtain a semiconductor device that hardly inhibits the flow of the current even when there is a dislocation that extends in the m-axis direction. In addition, according to the crystal growth method in the embodiment of the present disclosure, as described below, the semiconductor device includes substantially no dislocation in a direction that is vertical or substantially vertical to the m-axis direction may be obtained. Therefore, the semiconductor device illustrated in FIG. 6, in which current flows in the semiconductor layer at least in the first direction (m-axis direction) has enhanced semiconductor characteristics. In the embodiment of the present disclosure, it is preferred that the first plane of the semiconductor layer be a c-plane. According to such preferred aspect, it becomes possible to cause the electrical property of the semiconductor device 100 to be more satisfactory. In detail, the MOSFET in FIG. 6 includes the n−-type semiconductor layer 131a, a first n+-type semiconductor layer 131b, a second n+-type semiconductor layer 131c, the gate insulating film 134, a gate electrode 135a, the source electrode 135b, a drain electrode 135c, a buffer layer 138, and a semi-insulating layer 139. For example, as illustrated in FIG. 6, by embedding the n+-type semiconductor layer in the n−-type semiconductor layer, it becomes possible to cause the current to flow in a more satisfactory manner as compared to other horizontal MOSFETs. Also, as apparent from FIG. 6, current flows in the semiconductor layer (n−-type semiconductor layer) 131a at least in the first direction that is along with an interface between the semiconductor layer 131a and the gate electrode 135a (the gate insulating film 134).

The material of the electrode may be a well-known electrode material, and examples of the electrode material include metal such as Al, Mo, Co, Zr, Sn, Nb, Fe, Cr, Ta, Ti, Au, Pt, V, Mn, Ni, Cu, Hf, W, Ir, Zn, In, Pd, Nd, or Ag or an alloy thereof, metal oxide conductive films of tin oxide, zinc oxide, rhenium oxide, indium oxide, indium tin oxide (ITO), indium zinc oxide (IZO), and the like, an organic conductive compound such as polyaniline, polythiophene, or polypyrrole, or a mixture and a laminated body thereof.

The formation of the electrode is performable by well-known means such as vacuum deposition or spattering, for example. More specifically, for example, when an electrode is formed with use of two types of the metal, in other words, first metal and second metal out of the metal, it is possible to form the electrode by laminating a layer formed by the first metal and a layer formed by the second metal and applying patterning using an approach of photolithography on the layer formed by the first metal and the layer formed by the second metal.

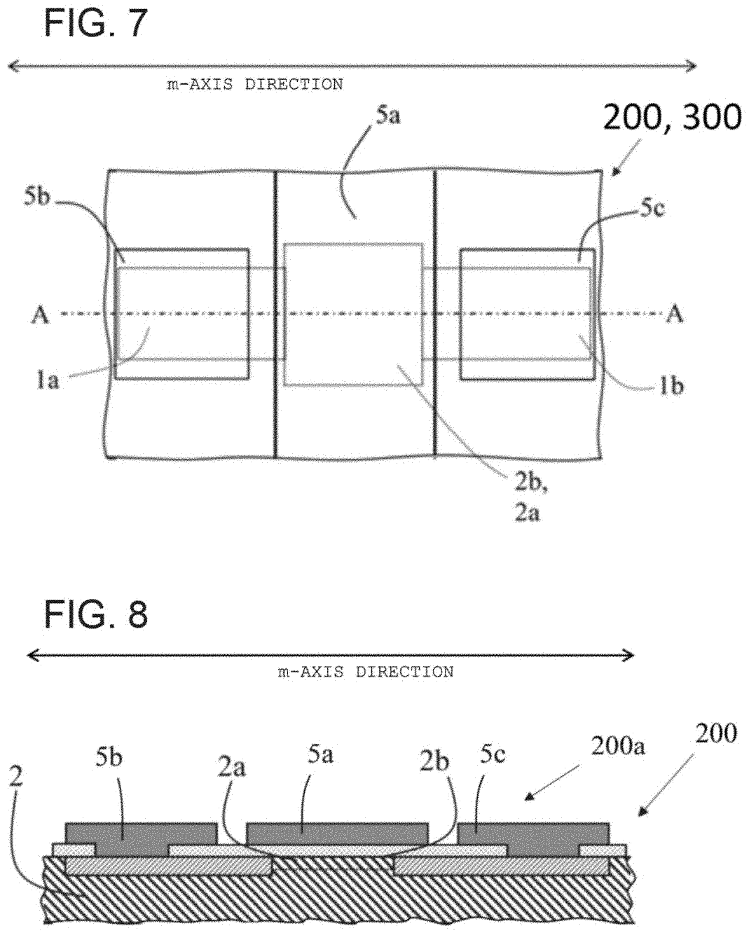

FIG. 7 illustrates a part of a schematic top view in order to describe main parts as one example of the semiconductor device in the embodiment of the present disclosure, but the number, shapes, and arrangement of the electrodes of the semiconductor device are selectable, as appropriate.

FIG. 8 illustrates a partial cross-sectional view for describing main parts as one example of the semiconductor device in the embodiment of the present disclosure, the partial cross-sectional view being a cross-section taken along line A-A of FIG. 7, for example. A semiconductor device 200 in the embodiment of the present disclosure at least has at least one semiconductor layer (for example, 2), and a first electrode (for example, 5b) and a second electrode (for example, 5c) each disposed on a first plane side 200a of the semiconductor device 200, in other words, the first plane side of a semiconductor layer 2. Current flows in a first direction from the first electrode toward the second electrode in the semiconductor layer. The semiconductor layer has a corundum structure, and the direction of the m-axis of the semiconductor layer is the first direction. In the embodiment of the present disclosure, it is preferred that the first plane of the semiconductor layer be a c-plane. According to such preferred aspect, it becomes possible to cause the electrical property of the semiconductor device to be more satisfactory. The semiconductor device 200 has an oxide semiconductor film containing crystal containing at least gallium oxide as the semiconductor layer 2. The semiconductor layer 2 includes an inverted channel region 2a. The crystal may contain gallium oxide as the major component, and the crystal may be mixed crystal. The semiconductor device 200 has an oxide film 2b in a position that comes into contact with the inverted channel region 2a. Also, as apparent from FIG. 8, current flows in the semiconductor layer 2 at least in the first direction that is along with an interface between the semiconductor layer 2 and the gate electrode 5a (the gate insulating film 4a). In addition, according to the crystal growth method in the embodiment of the present disclosure, as described below, the semiconductor device includes substantially no dislocation in a direction that is vertical or substantially vertical to the m-axis direction may be obtained (the semiconductor layer 2 may include a dislocation extending in a direction that is parallel or substantially parallel to the m-axis). Therefore, the semiconductor device illustrated in FIG. 8, in which current flows in the semiconductor layer at least in the first direction (m-axis direction), has enhanced semiconductor characteristics.

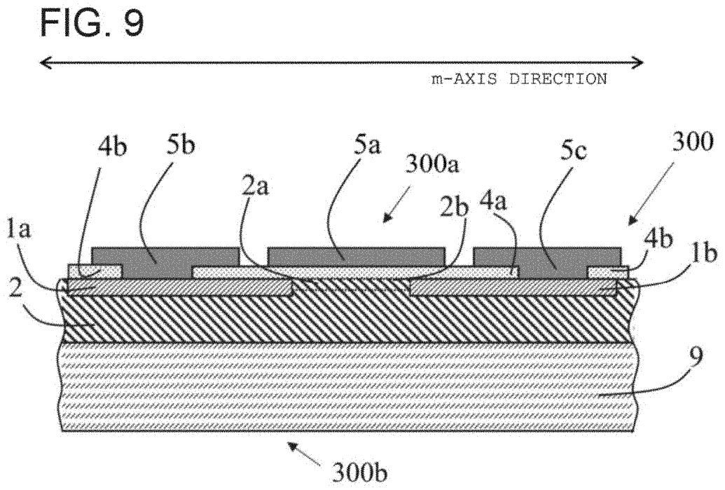

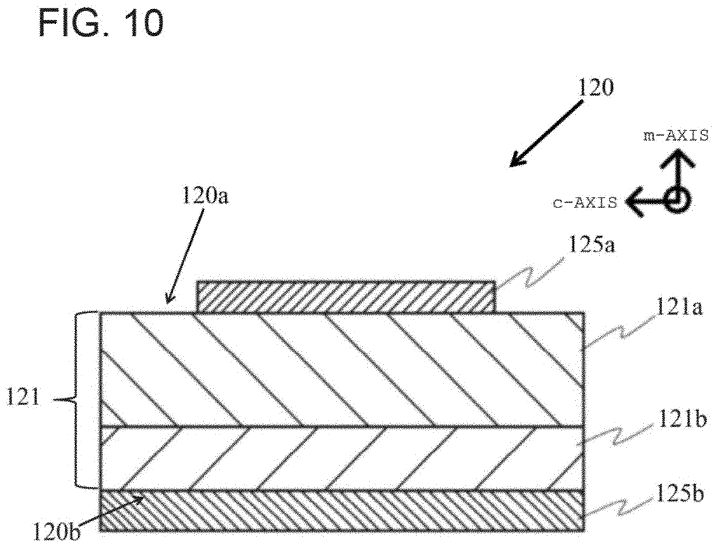

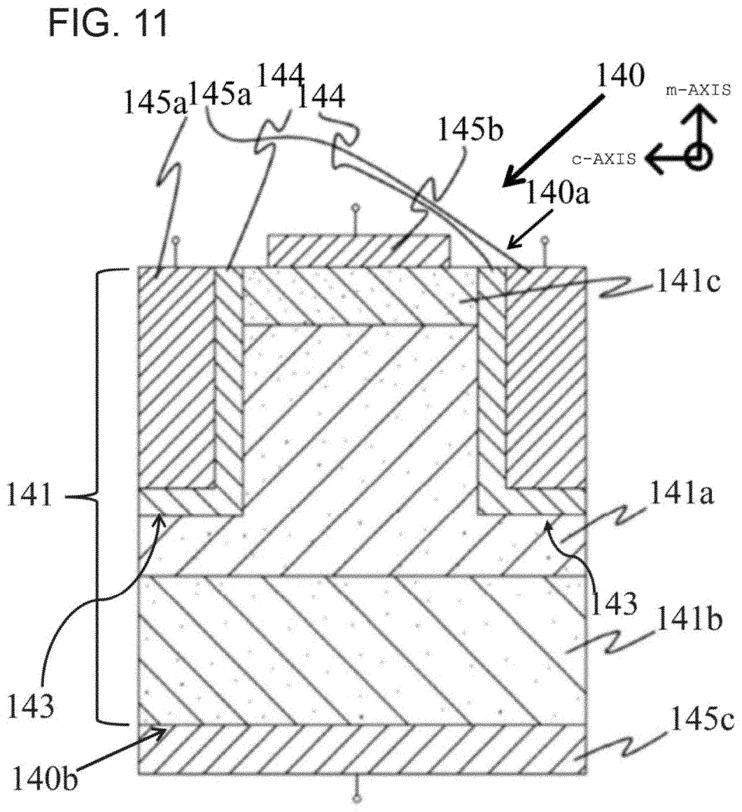

FIG. 9 illustrates a schematic cross-sectional view for describing a specific example as one example of the semiconductor device in the embodiment of the present disclosure, the schematic cross-sectional view being one specific example of a cross-section taken along line A-A of FIG. 7, for example. A semiconductor device 300 in the embodiment of the present disclosure at least has at least one semiconductor layer (for example, 2), and a first electrode (for example, 5b) and a second electrode (for example, 5c) each disposed on the first plane side of the semiconductor layer 2. Current flows in a first direction from the first electrode toward the second electrode in the semiconductor layer. The semiconductor layer has a corundum structure, and the direction of the m-axis of the semiconductor layer is parallel to the first direction. In the embodiment of the present disclosure, it is preferred that the first plane of the semiconductor layer be a c-plane. According to such preferred aspect, it becomes possible to cause the electrical property of the semiconductor device to be better. The semiconductor device 300 has an oxide semiconductor film containing crystal containing at least gallium oxide as the semiconductor layer 2, and the semiconductor layer 2 includes the inverted channel region 2a. The crystal has a corundum structure. The semiconductor device 300 has a first semiconductor region 1a and a second semiconductor region 1b. In the present embodiment, as illustrated in FIG. 9, the inverted channel region 2a is positioned between the first semiconductor region 1a and the second semiconductor region 1b in planar view. When voltage is applied to the semiconductor device 300, the inverted channel region of the semiconductor layer 2 is inverted. As a result, current is carried by the first semiconductor region 1a and the second semiconductor region 1b. In the present embodiment, the first semiconductor region 1a and the second semiconductor region 1b are positioned in the semiconductor layer 2, and the upper plane of the first semiconductor region 1a, the upper plane of the second semiconductor region 1b, and the upper plane of the inverted channel region 2a are disposed in the semiconductor layer 2 so as to be flush with each other. On a first plane side 300a of the semiconductor device 300, in other words, the first plane side of the semiconductor layer 2 (the upper plane side in the drawing), the semiconductor layer 2 that is an oxide semiconductor film including the first semiconductor region 1a and the inverted channel region 2a, and the second semiconductor region 1b configure a flat plane. As a result, designing including the arrangement of the electrodes becomes easier, which also leads to a thinner semiconductor device. As indicated below, a case where the oxide semiconductor film serving as the semiconductor layer 2 has the oxide film 2b provided in contact with an inverted channel region 2a2 is included in a case where the first semiconductor region 1a, the oxide semiconductor film serving as the semiconductor layer 2 including the inverted channel region 2a, and the second semiconductor region 1b have a flat plane. The first semiconductor region 1a and the second semiconductor region 1b may be embedded in the semiconductor layer 2 or may be disposed in the semiconductor layer 2 by ion implantation. The semiconductor layer 2 in the present embodiment is a p-type semiconductor film, and the first semiconductor region 1a and the second semiconductor region 1b are n-types. The semiconductor layer 2 may contain a p-type dopant. The semiconductor device 300 may have the oxide film 2b disposed on the inverted channel region 2a. In the embodiment of the present disclosure, it is also preferred that the oxide film 2b have a crystal structure belonging to a trigonal system to which the corundum structure belongs. The oxide film 2b contains at least one of elements in group 15 of the periodic table and preferably contains phosphorus. As another embodiment, the oxide film 2b may further contain at least one of elements in group 13 of the periodic table, and the semiconductor device 300 has the first electrode 5b electrically connected to the first semiconductor region 1a and the second electrode 5c electrically connected to the second semiconductor region 1b. The semiconductor device 300 has a third electrode 5a spaced apart from the inverted channel region 2a by an insulating film 4a between the first electrode 5b and the second electrode 5c. As illustrated in the drawing, the first electrode 5b, the second electrode 5c, and the third electrode 5a are disposed on the first plane side 300a of the semiconductor device 300, in other words, the first plane side of the semiconductor layer 2. In detail, the semiconductor device 300 has the insulating film 4a disposed on the oxide film 2b on the inverted channel region 2a, and the third electrode 5a is disposed on the insulating film 4a. In the semiconductor device 300, the first electrode 5b and the first semiconductor region 1a are electrically connected to each other, but an insulating film 4b partially positioned between the first electrode 5b and the first semiconductor region 1a may be included. The second electrode 5c and the second semiconductor region 1b are electrically connected to each other, but the insulating film 4b also partially positioned between the second electrode 5c and the second semiconductor region 1b may be included. The semiconductor device 300 may have another layer on a second plane side 300b of the semiconductor device 300, in other words, the second plane side of the semiconductor layer 2 (the lower plane side in the drawing) and may have a substrate 9 as illustrated in FIG. 9. As illustrated in FIG. 7, the first semiconductor region 1a has a part that overlaps with the first electrode 5b and a part that overlaps with the third electrode 5a in planar view. The second semiconductor region 1b has a part that overlaps with the second electrode 5c and a part that overlaps with the third electrode 5a in planar view. In the present embodiment, when positive voltage with respect to the first electrode 5b is applied to the third electrode 5a, the inverted channel region 2a of the semiconductor layer 2 is inverted from the p-type to the n-type, an n-type channel layer is formed, the first semiconductor region 1a and the second semiconductor region 1b carry current, and electrons flow from a source electrode to a drain electrode. By causing the voltage of the third electrode 5a to be zero, the channel layer stops being formed in the inverted channel region 2a, and turning OFF is performed. In the present embodiment, for example, the first electrode 5b may be a source electrode, the second electrode 5c may be a drain electrode, and the third electrode 5a may be a gate electrode. In this case, the insulating film 4a is a gate insulating film, and the insulating film 4b is a field insulating film. Also, as apparent from FIG. 9, current flows in the semiconductor layer 2 at least in the first direction that is along with an interface between the semiconductor layer 2 and the gate electrode 5a (the gate insulating film 4a).

FIG. 10 illustrates one example of a Schottky barrier diode (SBD) as a semiconductor device 120 according to the embodiment of the present disclosure. The semiconductor device 120 has a first electrode 125a disposed on a first plane side 120a of a semiconductor layer 121, and a second electrode 125b disposed on a second plane side 120b that is a side opposite from the first plane side 120a. In the present embodiment, the semiconductor layer 121 includes an n−-type semiconductor layer as a first semiconductor layer 121a, and an n+-type semiconductor layer as a second semiconductor layer 121b disposed in contact with the first semiconductor layer 121a. The first electrode 121a disposed on the first semiconductor layer 121a is a Schottky electrode 125a. The second electrode disposed on the second semiconductor layer 121b is the ohmic electrode 125b. In the present embodiment, the first plane is an m-plane, the second electrode is longer than the first electrode in at least a first direction, and the first direction is the c-axis direction of the semiconductor layer. It is possible to cause the direction in which the current flows from the first electrode 121a to the second electrode 125b to be parallel to the m-axis direction. Therefore, it becomes possible to obtain a semiconductor device that hardly inhibits the flow of the current even when there is a dislocation that extends in the m-axis direction.

The materials of the Schottky electrode and the ohmic electrode may be well-known electrode materials, and examples of the electrode materials include metal such as Al, Mo, Co, Zr, Sn, Nb, Fe, Cr, Ta, Ti, Au, Pt, V, Mn, Ni, Cu, Hf, W, Ir, Zn, In, Pd, Nd, or Ag or an alloy thereof, a metal oxide conductive film of tin oxide, zinc oxide, rhenium oxide, indium oxide, indium tin oxide (ITO), indium zinc oxide (IZO), and the like, an organic conductive compound such as polyaniline, polythiophene, or polypyrrole, or a mixture and a laminated body thereof.

The formation of the Schottky electrode and the ohmic electrode is performable by well-known means such as vacuum deposition or spattering, for example. More specifically, for example, when the Schottky electrode is formed with use of two types of metal, in other words, first metal and second metal out of the metal, it is possible to form the electrode by laminating a layer formed by the first metal and a layer formed by the second metal and applying patterning using an approach of photolithography on the layer formed by the first metal and the layer formed by the second metal.

When a reverse bias is applied to the SBD in FIG. 10, a depletion layer (not shown) spreads in the n−-type semiconductor layer 121a, and hence an SBD with high voltage resistance is obtained. When a forward bias is applied, electrons flow from the ohmic electrode 125b to the Schottky electrode 125a. The SBD using the semiconductor structure as above is excellent for high voltage resistance and high current, has high switching speed, and is also excellent in terms of voltage resistance property and reliability.

### (MOSFET)

FIG. 11 illustrates a MOSFET as a semiconductor device 140 according to the embodiment of the present disclosure. The semiconductor device 140 has a second electrode 145c disposed on a second plane side 140b that is a side opposite from a first plane side 140a of a semiconductor layer (also referred to as a semiconductor film) 141. The MOSFET in FIG. 11 is a trench-type MOSFET. In the present embodiment, the semiconductor layer 141 has a plurality of laminated layers. The semiconductor device 140 includes a source electrode as a first electrode 145b, a drain electrode as the second electrode 145c, and gate electrodes as third electrodes 145a.

When description is made from the lower side of FIG. 11, an n+-type semiconductor layer 141b having a thickness of from 100 nm to 100 μm, for example, is formed on the drain electrode 145c, and an n−-type semiconductor layer 141a having a thickness of from 100 nm to 100 μm, for example, is formed on the n+-type semiconductor layer 141b. An n+-type semiconductor layer 141c is formed on the n−-type semiconductor layer 141a, and the source electrode 145b is formed on the n+-type semiconductor layer 141c.

The semiconductor layer 141 has at least one trench 143, and the depth direction of the at least one trench 143 is a direction parallel to the m-axis of the semiconductor layer. In the embodiment of the present disclosure, the semiconductor layer 141 has a plurality of semiconductor layers, and a plurality of the trenches 143 are disposed. The semiconductor layer 141 has the n−-type semiconductor layer serving as the first semiconductor layer 141a, the n+-type semiconductor layer serving as the second semiconductor layer 141b disposed in contact with the second plane side of the first semiconductor layer 141a, and the n+-type semiconductor layer serving as the third semiconductor layer 141c disposed in contact with a first plane of the first semiconductor layer 141a. In the present embodiment, the trenches 143 pass through the third semiconductor layer (n+ semiconductor layer) 141c, and the plurality of trenches 143 with a depth that reaches to a place in the middle of the first semiconductor layer (n−-type semiconductor layer) 141a are formed. In each of the trenches 143, the gate electrode 145a is formed in an embedded manner via a gate insulating film 144 having a thickness of from 10 nm to 1 μm, for example.

In the ON state of the MOSFET in FIG. 11, when voltage is applied across the source electrode 145b and the drain electrode 145c and positive voltage with respect to the source electrode 145b is applied to the gate electrodes 145a, channel layers are formed on side planes of the n−-type semiconductor layer 141a, electrons are injected into the n−-type semiconductor layer 141a, and turning ON is performed. Regarding the OFF state, the voltage across the gate electrodes is caused to be 0 V. As a result, the channel layers are stopped from being formed, the n−-type semiconductor layer 141a is placed in a state of being filled with a depletion layer, and turning OFF is performed. Also, as apparent from FIG. 11, current flows in the semiconductor layer 141a at least in the first direction that is along with an interface between the semiconductor layer (n−-type semiconductor layer) 141a and the gate electrode 145a (the gate insulating film 144). In addition, according to the crystal growth method in the embodiment of the present disclosure, as described below, the semiconductor device includes substantially no dislocation in a direction that is vertical or substantially vertical to the m-axis direction may be obtained (the semiconductor layer 141a may include a dislocation extending in a direction that is parallel or substantially parallel to the m-axis). Therefore, the semiconductor device illustrated in FIG. 11, in which current flows in the semiconductor layer at least in the first direction (m-axis direction), has enhanced semiconductor characteristics.

### (IGBT)

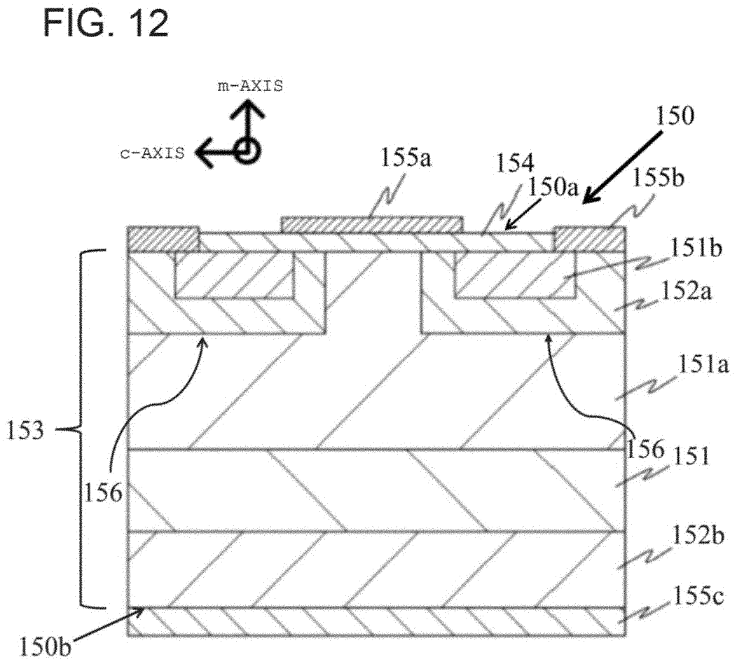

FIG. 12 illustrates one suitable example of an insulated gate bipolar transistor (IGBT) as a semiconductor device 150 according to the embodiment of the present disclosure. The semiconductor device 150 has a semiconductor layer 153 (also referred to as a semiconductor film). The semiconductor device 150 has a first electrode 155b disposed on a first plane side 150a of the semiconductor layer (also referred to as the semiconductor film) 153, a third electrode 155a, and a second electrode 155c disposed on a second plane side 150b that is a side opposite from the first plane side 150a. The semiconductor layer 153 has at least one trench 156, and the depth direction of the at least one trench 156 is a direction parallel to the m-axis of the semiconductor layer. In the embodiment of the present disclosure, the semiconductor layer 153 has a plurality of semiconductor layers, and a plurality of the trenches 156 are disposed. As a first semiconductor layer 151a, an n−-type semiconductor layer is disposed, and trenches 156 with a depth to a place in the middle of heading toward the second plane side from the first plane side of the first semiconductor layer (in the present embodiment, the n−-type semiconductor layer) 151a are disposed. A p-type semiconductor region 152a is disposed in each of the trenches 156, and an n+-type semiconductor region 151b is disposed in the p-type semiconductor region 152a. The semiconductor device 150 further has, on the second plane side of the first semiconductor layer 151a, a second semiconductor layer 151 (in the present embodiment, an n-type semiconductor layer 151) disposed in contact with the first semiconductor layer 151a, and a third semiconductor layer 152b (in the present embodiment, a p-type semiconductor layer) disposed in contact with a second plane of the second semiconductor layer 151. In the present embodiment, a gate insulating film 154 is disposed on the first plane side 150a of the semiconductor layer 153, and the gate electrode 155a is disposed on the gate insulating film 154. Emitter electrodes 155b disposed on the p-type semiconductor region 152 on the first plane side 150a of the semiconductor layer 153, and a collector electrode as the second electrode 155c disposed in contact with the p-type semiconductor layer 152b positioned on the second plane side 150b of the semiconductor layer 153 are included. Also, as apparent from FIG. 12, current flows in the semiconductor layer 151a at least in the first direction that is along with an interface between the semiconductor layer (n−-type semiconductor layer) 151a and the gate electrode 155a (the gate insulating film 154). In addition, according to the crystal growth method in the embodiment of the present disclosure, as described below, the semiconductor device includes substantially no dislocation in a direction that is vertical or substantially vertical to the m-axis direction may be obtained (the semiconductor layer 151a may include a dislocation extending in a direction that is parallel or substantially parallel to the m-axis). Therefore, the semiconductor device illustrated in FIG. 12, in which current flows in the semiconductor layer at least in the first direction (m-axis direction), has enhanced semiconductor characteristics.

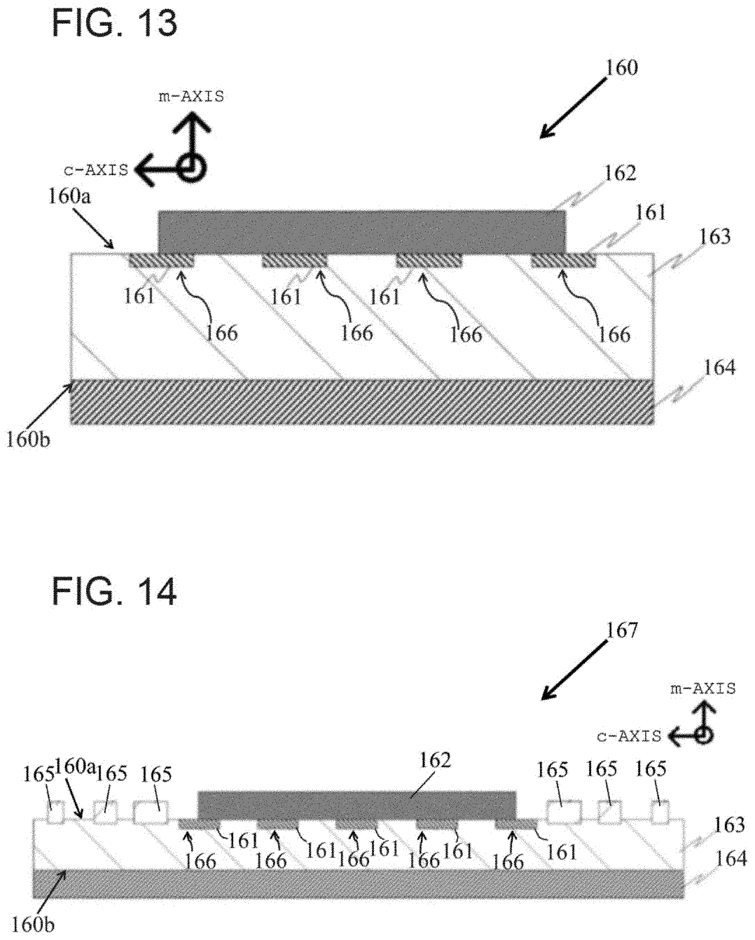

FIG. 13 illustrates a junction barrier Schottky diode (JBS) as a semiconductor device 160 according to the embodiment of the present disclosure. The semiconductor device 160 has a semiconductor layer 163 (also referred to as a semiconductor film). The semiconductor device 160 has a first electrode 162 disposed on a first plane side 160a of the semiconductor layer 163, and a second electrode 164 disposed on a second plane side 160b that is a side opposite from the first plane side 160a of the semiconductor layer 163. The semiconductor layer 163 has at least one trench 166, and the depth direction of the at least one trench 166 is a direction parallel to the m-axis of the semiconductor layer. In the embodiment of the present disclosure, the semiconductor layer 163 may include a plurality of semiconductor layers. A plurality of the trenches 166 may be disposed. The semiconductor device in FIG. 13 that is one preferred embodiment of the present disclosure includes the semiconductor layer 163, the barrier electrode 162 provided on the semiconductor layer 163 and capable of forming a Schottky barrier between the barrier electrode 162 and the semiconductor layer 163, and barrier height adjustment regions 161 provided between the barrier electrode 162 (first electrode) and the semiconductor layer 163 and capable of forming, between the barrier height adjustment regions 161 and the semiconductor layer 163, a Schottky barrier having a greater barrier height than the barrier height of the Schottky barrier of the barrier electrode 162. The barrier height adjustment regions 161 are embedded in the trenches 166 formed in the semiconductor layer 163. In the present embodiment, it is preferred that the barrier height adjustment regions 161 be provided at a certain interval, and it is more preferred that each of the barrier height adjustment regions 161 be provided between both ends of the barrier electrode 162 and the semiconductor layer 163. By such preferred aspect, the JBS is configured to be better in terms of thermal stability and adhesiveness, have less leakage current, and be excellent in terms of semiconductor properties such as voltage resistance. The semiconductor device in FIG. 13 includes the ohmic electrode 164 (second electrode) disposed on the semiconductor layer 163.

Formation means for each layer of the semiconductor device in FIG. 13 is not particularly limited unless it interferes with the present disclosure and may be well-known means. Examples include means for directly performing patterning with use of a printing technique or means for performing patterning by photolithography after forming a film by vacuum deposition, CVD, spattering, various coating techniques, and the like.

FIG. 14 illustrates a junction barrier Schottky diode (JBS) as a semiconductor device 167 according to the embodiment of the present disclosure. The semiconductor device 167 has the semiconductor layer 163 (also referred to as the semiconductor film). The semiconductor device 167 has the first electrode 162 disposed on the first plane side 160a of the semiconductor layer 163, and the second electrode 164 disposed on the second plane side 160b that is the side opposite from the first plane side 160a of the semiconductor layer 163. The semiconductor layer 163 has at least one trench 161, and the depth direction of the at least one trench 161 is a direction parallel to the m-axis of the semiconductor layer 163. In the embodiment of the present disclosure, the semiconductor layer 163 may have a plurality of semiconductor layers. A plurality of the trenches 161 are disposed. The semiconductor device in FIG. 14 is different from the semiconductor device in FIG. 13 in that guard rings 165 are provided on outer peripheral portions of the barrier electrode. By the configuration as above, it becomes possible to obtain a semiconductor device better in terms of semiconductor properties such as voltage resistance. In the present disclosure, it becomes possible to cause the voltage resistance to be more effective and more satisfactory by embedding a part of each of the guard rings 165 in the first plane of the semiconductor layer 163. By using metal having a high barrier height in the guard rings, it becomes possible to provide the guard rings with the formation of the barrier electrode in an industrially advantageous manner and form the guard rings without affecting the semiconductor region so much and without deteriorating the ON resistance.

A material having a high barrier height is normally used in the guard rings. Examples of the material used in the guard rings include an electrically conducting material of which barrier height is 1 eV or more and the material may be the same as the electrode material. In the present disclosure, it is preferred that the material used in the guard ring be the metal because the design freedom of a voltage-resistant structure is high, a large number of guard rings are providable, and it becomes possible to flexibly cause the voltage resistance to be more satisfactory. The shape of each of the guard rings is not particularly limited and examples thereof include a hollow quadrilateral shape, a circular shape, a squared U-shape, an L-shape, and a strip-like shape. The number of the guard rings is not particularly limited either but is preferably three or more and is more preferably six or more.

The oxide semiconductor film containing crystal containing gallium oxide and/or the oxide semiconductor film containing crystal having a corundum structure are obtainable by performing film formation with use of a method of epitaxial crystal growth. The method of epitaxial crystal growth is not particularly limited unless it interferes with the present disclosure and may be well-known means. Examples of the method of epitaxial crystal growth include CVD, metal organic chemical vapor deposition (MOCVD), metalorganic vapor-phase epitaxy (MOVPE), mist CVD, mist epitaxy, molecular beam epitaxy (MBE), hydride vapor phase epitaxy (HVPE), or pulsed growth. In the embodiment of the present disclosure, it is preferred that the mist CVD or the mist epitaxy be used when the oxide semiconductor film is formed by the epitaxial crystal growth.

Examples of the material of the first electrode, the second electrode, and/or the third electrode include metal such as Al, Mo, Co, Zr, Sn, Nb, Fe, Cr, Ta, Ti, Au, Pt, V, Mn, Ni, Cu, Hf, W, Ir, Zn, In, Pd, Nd, or Ag or an alloy thereof, a metal oxide conductive film of tin oxide, zinc oxide, rhenium oxide, indium oxide, indium tin oxide (ITO), indium zinc oxide (IZO), and the like, an organic conductive compound such as polyaniline, polythiophene, or polypyrrole, or a mixture thereof. The film formation method of the electrodes is not particularly limited, and the electrodes are formable on the substrate in accordance with a method selected, as appropriate, from a wet method such as printing, spraying, and coating, a physical method such as vacuum deposition, spattering, and ion plating, a chemical method such as CVD and plasma CVD, and the like by taking suitability with respect to the material into consideration.

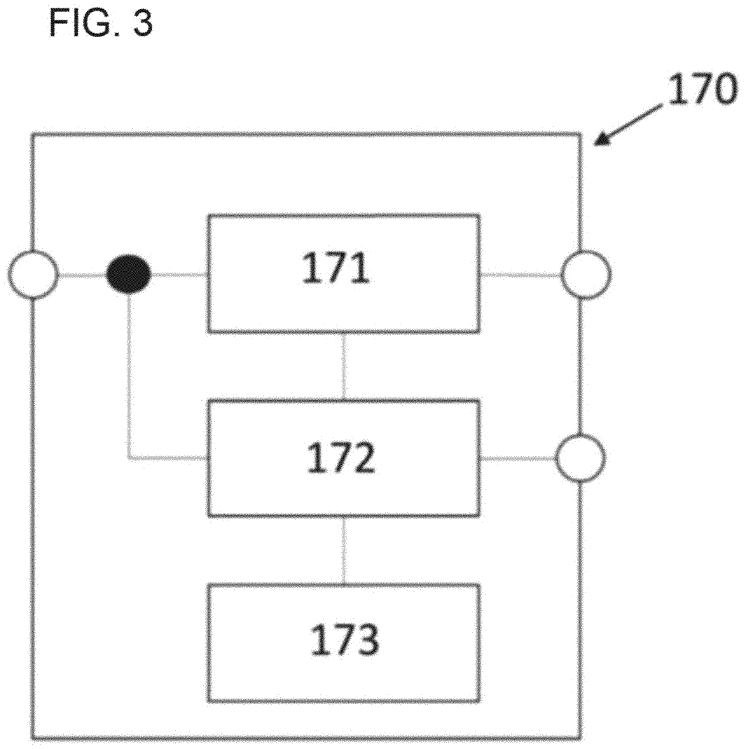

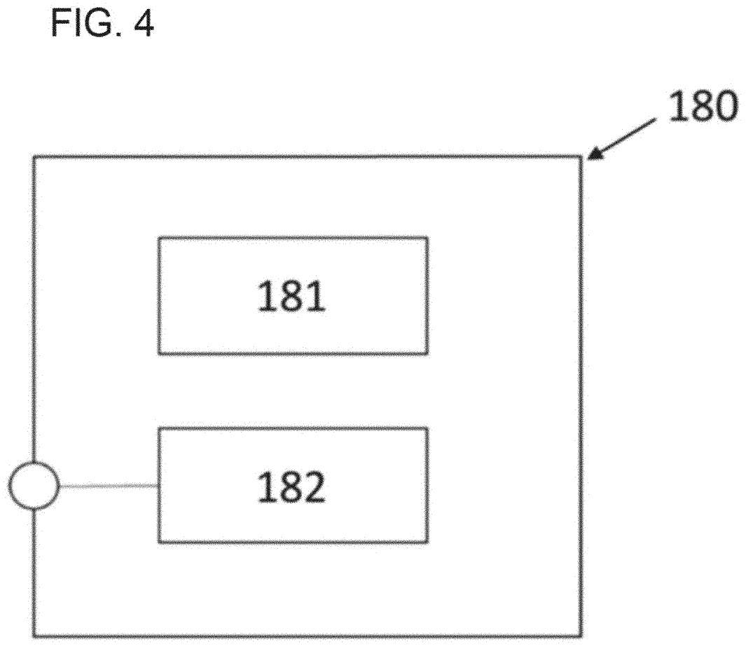

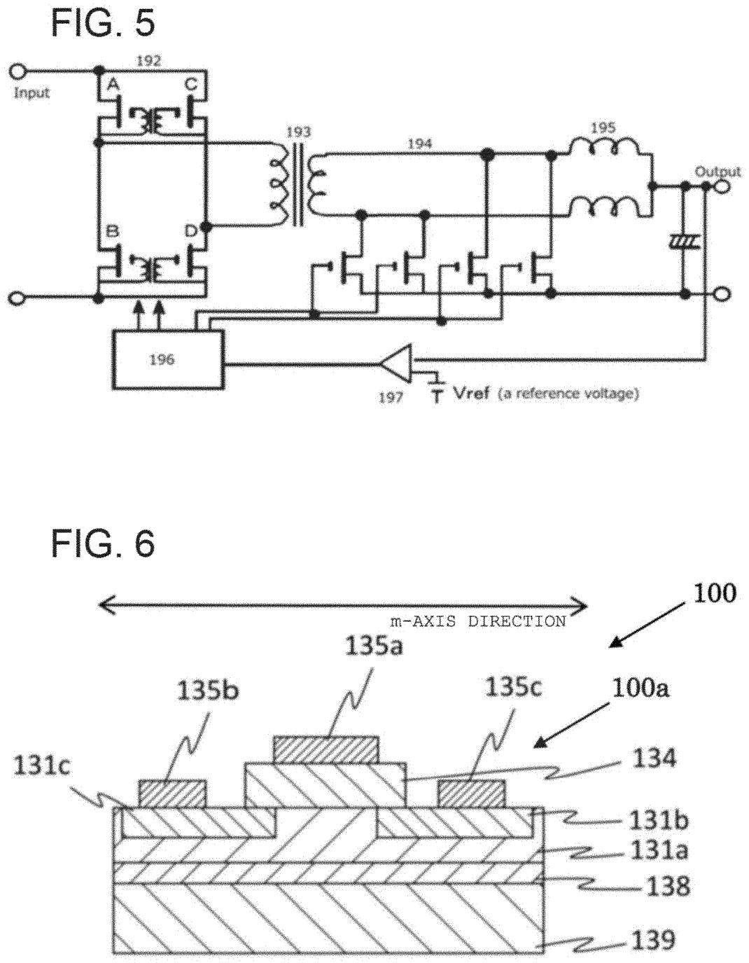

In addition to the abovementioned features, by further using a well-known method, the semiconductor device in the embodiment of the present disclosure is suitably used as a power module, an inverter, or a converter, and is further suitably used in a semiconductor system using a power source apparatus, for example. The power source apparatus is producible from the semiconductor device or as the semiconductor device by connection to a wiring pattern and the like by a common procedure. FIG. 3 configures a power source system 170 with use of a plurality of power source apparatuses 171, 172 described above and a control circuit 173. As illustrated in FIG. 4, the power source system is usable in a system apparatus 180 by combining an electronic circuit 181 and a power source system 182. One example of a power source circuit diagram of the power source apparatus is illustrated in FIG. 5. FIG. 5 illustrates a power source circuit of the power source apparatus formed by a power circuit and a control circuit. DC voltage is converted to AC by performing switching at a high frequency by an inverter 192 (configured by MOSFETs A to D). Then, insulation and transformation are performed by a transformer 193, and rectification is performed by a rectification MOSFET 194. Then, smoothing is performed by a DCL 195 (smoothing coils L1, L2) and a capacitor, and DC voltage is output. At this time, the output voltage is compared with reference voltage by a voltage comparator 197, and the inverter 192 and the rectification MOSFET 194 are controlled by a PWM control circuit 196 such that desired output voltage is obtained.

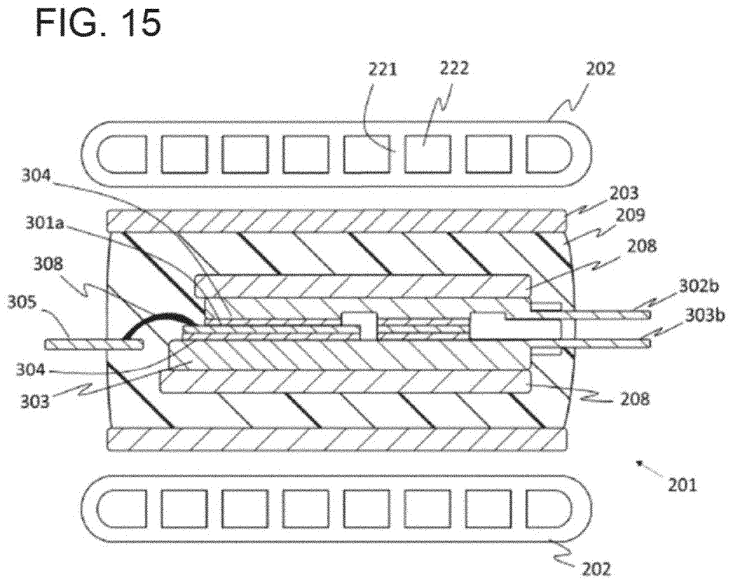

In the present disclosure, it is preferred that the semiconductor device be a power card. It is more preferred that the semiconductor device include a cooler and an insulation member, and the cooler be provided on each of both sides of the semiconductor layer via at least the insulation member. It is most preferred that a heat release layer be provided on each of both sides of the semiconductor layer, and the cooler be provided on the outer side of the heat release layer via at least the insulation member. FIG. 15 illustrates a power card that is one preferred embodiment of the present disclosure. The power card in FIG. 15 is a both-plane-cooling-type power card 201 and includes refrigerant tubes 202, spacers 203, insulating plates (insulating spacers) 208, a sealing resin portion 209, a semiconductor chip 301a, a metal heat transfer plate (protruding terminal portion) 302b, a heat sink and an electrode 303, a metal heat transfer plate (protruding terminal portion) 303b, a solder layer 304, a control electrode terminal 305, and bonding wire 308. The cross-section of each of the refrigerant tubes 202 in the thickness direction has a large number of flow paths 222 partitioned by a large number of dividing walls 221 extending in the flow path direction so as to be spaced apart from each other at a predetermined interval. According to such suitable power card, it becomes possible to realize higher heat release property and satisfy higher reliability.

The semiconductor chip 301a is joined onto a principal plane on the inner side of the metal heat transfer plate 302b by a solder layer 104, and the metal heat transfer plate (protruding terminal portion) 302b is joined to the remaining principal plane of the semiconductor chip 301a by the solder layer 304. As a result, an anode electrode plane and a cathode electrode plane of a flywheel diode are connected to a collector electrode plane and an emitter electrode plane of the IGBT in a so-called antiparallel manner. Examples of the material of the metal heat transfer plates (protruding terminal portions) 302b and 303b include Mo or W. The metal electric heating plates (protruding terminal portions) 302 and 303b have a difference in thickness that absorbs the difference in thickness between semiconductor chips 101a, 101b. As a result, an outer surface of the metal heat transfer plate 102 becomes a planar surface.

The sealing resin portion 209 is formed by epoxy resin, for example, and is molded so as to cover side planes of the metal heat transfer plates 302b and 303b. The semiconductor chip 301a is molded with the sealing resin portion 209. However, outer principal planes, in other words, contact heat-receiving planes of the metal heat transfer plates 302b and 303b are fully exposed. The metal heat transfer plates (protruding terminal portions) 302b and 303b protrude to the right side in FIG. 15 from the sealing resin portion 209. The control electrode terminal 305 that is a so-called lead frame terminal connects the control electrode terminal 305 and a gate (control) electrode plane of the semiconductor chip 301a on which the IGBT is formed, for example.

The insulating plates 208 that are insulating spacers are configured by aluminum nitride film, for example, but may be other insulating films. The insulating plates 208 completely cover the metal heat transfer plates 302b and 303b in close contact therewith. However, the insulating plates 208 and the metal heat transfer plates 302b and 303b may simply be in contact with each other, a material with satisfactory heat transfer property such as silicone grease may be applied, or the insulating plates 208 and the metal heat transfer plates 302b and 303b may be joined to each other by various methods. An insulating layer may be formed by ceramic spraying and the like, or the insulating plates 208 may be joined onto the metal heat transfer plates or may be joined onto or formed on the refrigerant tubes.

The refrigerant tube 202 is produced by cutting a plate material obtained by performing pultrusion molding or extrusion molding of an aluminum alloy into necessary lengths. The cross-section of each of the refrigerant tubes 202 in the thickness direction has a large number of the flow paths 222 partitioned by a large number of the dividing walls 221 extending in the flow path direction so as to be spaced apart from each other at a predetermined interval. The spacers 203 may be soft metal plates of a solder alloy and the like, but also may be films formed by application and the like onto contact planes of the metal heat transfer plates 302b and 303b. The surface of each of the soft spacers 3 easily deforms and reduces thermal resistance by fitting with minute unevenness and a warp of the insulating plate 208 and minute unevenness and a warp of the refrigerant tube 202. Well-known grease with satisfactory thermal conductivity and the like may be applied to the surface and the like of each of the spacers 203, or the spacers 203 may be omitted.

### EXAMPLE 1

### 1. Formation of ELO Mask

By using a sapphire substrate (a c-plane, an off-angle of 0.25 degrees) having a surface on which an α-Ga₂O₃ layer was formed as a substrate, a mask layer formed by titanium oxide was formed on the substrate with use of spattering. Then, the formed mask layer was processed into a mask having a predetermined shape with use of photolithography. Specifically, a mask layer (a thickness of 50 nm) of titanium oxide (TiO₂) was formed by spattering while by causing O₂ gas and Ar gas to flow. A plurality of openings (dot-like openings) (diameter: 3 μm) were formed with use of photolithography. The mask layer was processed such that the plurality of openings were arranged on the substrate such that the distance from the center of each of the openings to the center of the nearest neighboring opening was 25 μm and the centers of openings were positioned in the vertices of a triangular lattice (an equilateral triangular lattice in the present example).

### 2. Formation of Crystal

### 2-1. HVPE Apparatus

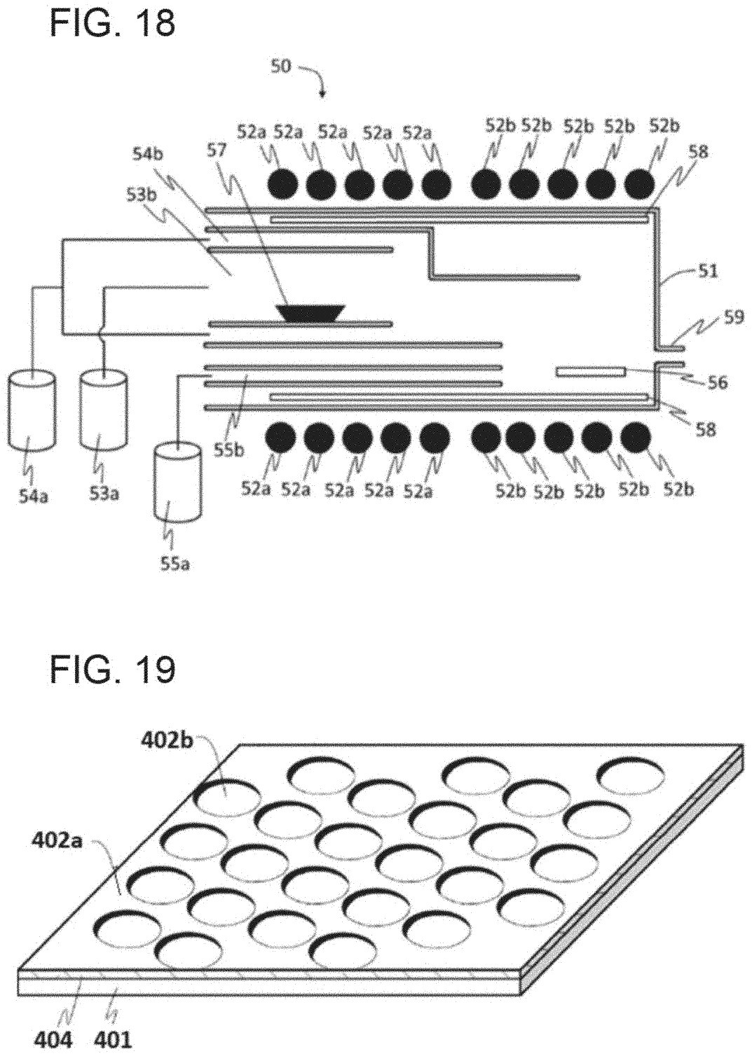

A hydride vapor phase epitaxy (HVPE) apparatus 50 used in the present example is described with reference to FIG. 18. The HVPE apparatus 50 includes a reaction chamber 51, heaters 52a that heat a metal source 57 and heaters 52b that heat a substrate fixed to a substrate holder 56, and further includes an oxygen-containing-raw-material-gas supply pipe 55b, a reactive-gas supply pipe 54b, and the substrate holder 56 on which the substrate is installed in the reaction chamber 51. In the reactive-gas supply pipe 54b, a metal-containing-raw-material-gas (metal-halide-gas) supply pipe 53b is included, and a double-pipe structure is formed. The oxygen-containing-raw-material-gas supply pipe 55b is connected to an oxygen-containing-raw-material-gas supply source 55a and forms a flow path of oxygen-containing raw material gas such that the oxygen-containing raw material gas is suppliable to the substrate fixed to the substrate holder 56 from the oxygen-containing-raw-material-gas supply source 55a via the oxygen-containing-raw-material-gas supply pipe 55b. The reactive-gas supply pipe 54b is connected to a reactive-gas supply source 54a and configures a flow path of reactive gas such that the reactive gas is suppliable to the substrate fixed to the substrate holder 56 from the reactive-gas supply source 54a via the reactive-gas supply pipe 54b. The metal-containing-raw-material-gas supply pipe 53b is connected to a halide-containing-raw-material-gas supply source 53a. Halide-containing raw material gas is supplied to the metal source and becomes metal-containing raw material gas, and the metal-containing raw material gas is supplied to the substrate fixed to the substrate holder 56. A gas discharge portion 59 that exhausts used gas is provided in the reaction chamber 51, and a protective sheet 58 that prevents deposition of a reactant is installed on an inner wall of the reaction chamber 51.

### 2-2. Film Formation Preparation

The gallium (Ga) metal source 57 (a purity of 99.99999% or more) was disposed in the metal-containing-raw-material-gas supply pipe 53b, and the sapphire substrate with the mask layer obtained in 1. described above was installed on the substrate holder 56 in the reaction chamber 51 as the substrate. Then, the heaters 52a and 52b were actuated, and the temperature in the reaction chamber 51 was raised to 570° C. (around the Ga metal source) and 540° C. (around the substrate holder).

### 2-3. Film Formation

Hydrogen chloride (HCl) gas (a purity of 99.999% or more) was supplied to the gallium (Ga) metal 57 disposed in the metal-raw material-containing gas supply pipe 53b from the halide-containing-raw-material-gas supply source 53a. Gallium chloride (GaCl/GaCl₃) was generated by a chemical reaction between the Ga metal and the hydrogen chloride (HCl) gas. The obtained gallium chloride (GaCl/GaCl₃) and O₂ gas (a purity of 99.99995% or more) supplied from the oxygen-containing-raw-material-gas supply source 55a were supplied onto the substrate through the reactive-gas supply pipe 54b. Then, film formation was performed on the substrate by causing the gallium chloride (GaCl/GaCl₃) and the O₂ gas to react on the substrate under atmospheric pressure at 540° C. under the distribution of the HCl gas. The flow rate of the HCl gas supplied from the halide-containing-raw-material-gas supply source 53a was maintained at 10 sccm, the flow rate of the HCl gas supplied from the reactive-gas supply source 54a was maintained at 10 sccm, and the flow rate of the O₂ gas supplied from the oxygen-containing oxygen-containing-raw-material-gas supply source 55a was maintained at 100 sccm.

### 2-4. Evaluation

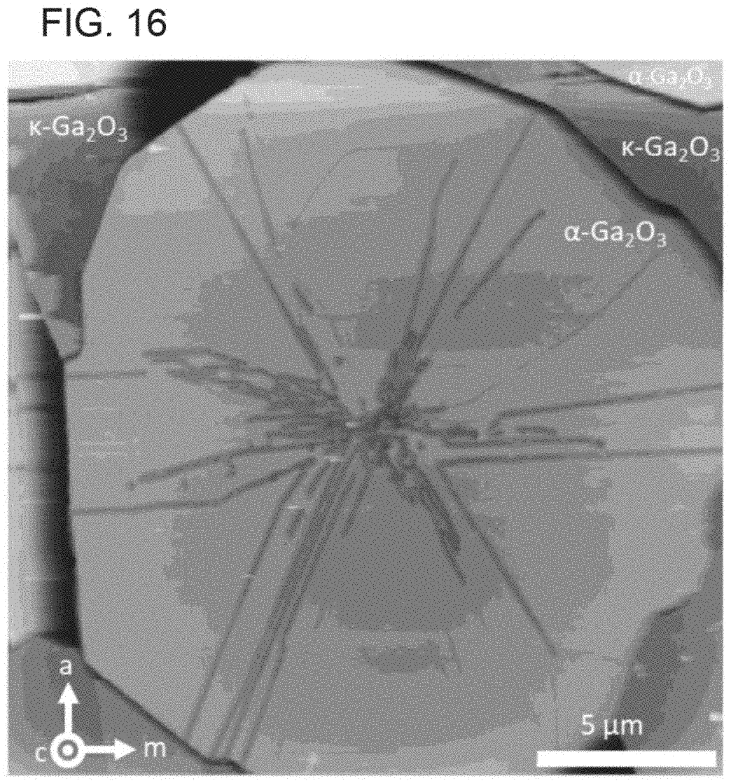

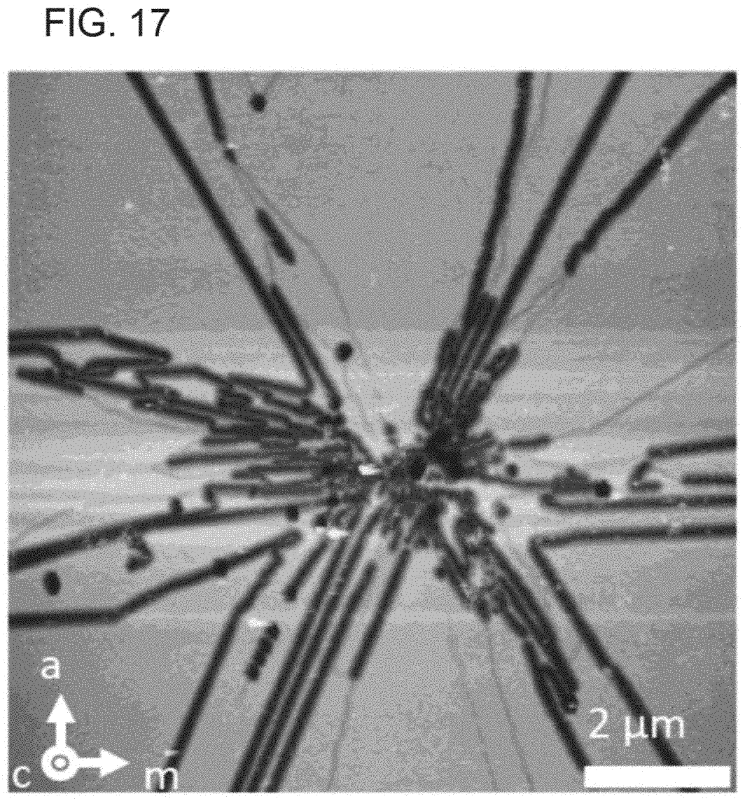

Regarding the multilayer structure obtained in 2-3. described above, atomic force microscope (AFM) observation was performed after surface polishing and washing. The result is shown in FIG. 16. A partially enlarged view of a central portion of FIG. 16 is shown in FIG. 17. As it is clear from FIG. 16 and FIG. 17, an anisotropy in which dislocation does not extend in the a-axis direction and dislocation extends in the m-axis direction was found. It was also found that dislocation in the c-axis direction was also reduced because the dislocation in the m-axis direction extended.

### EXAMPLE 2

### 1. Formation of ELO Mask

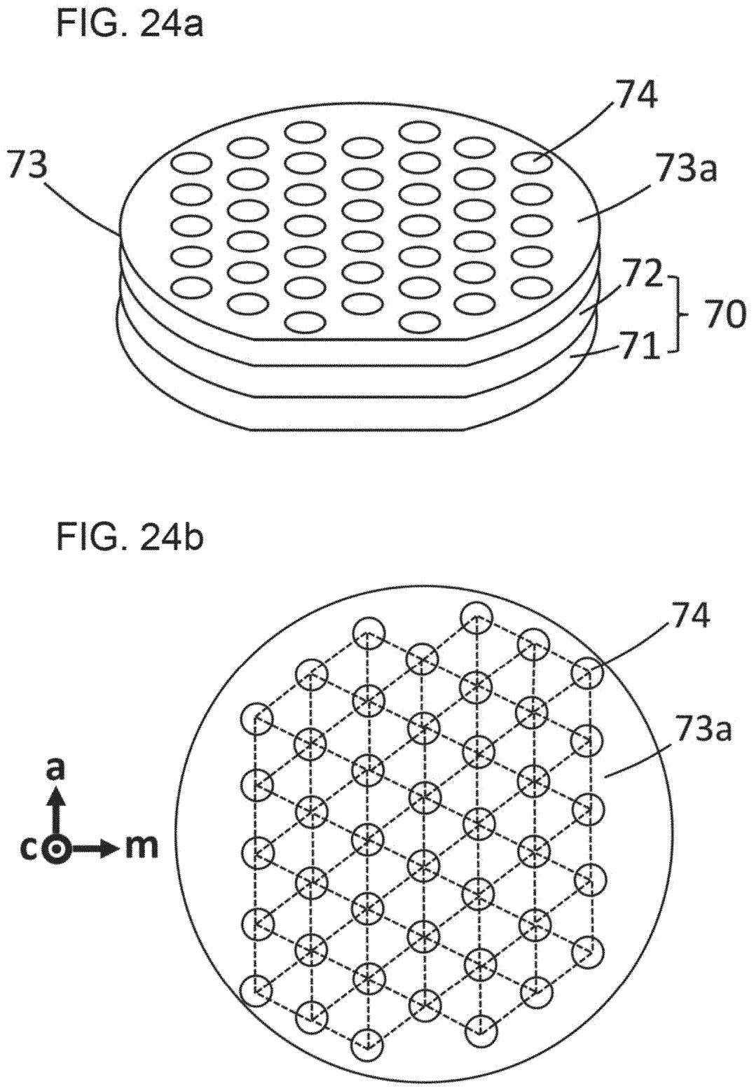

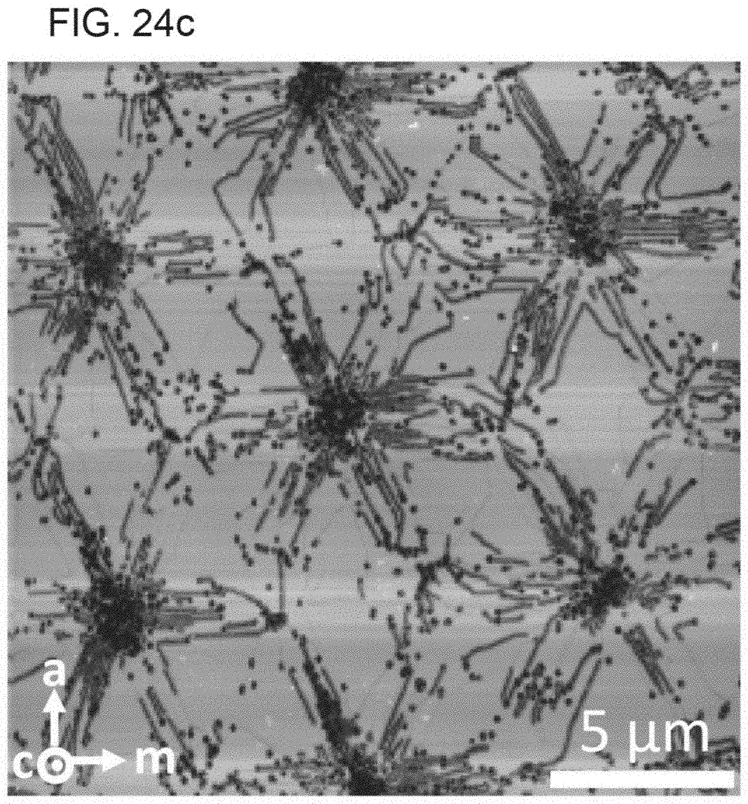

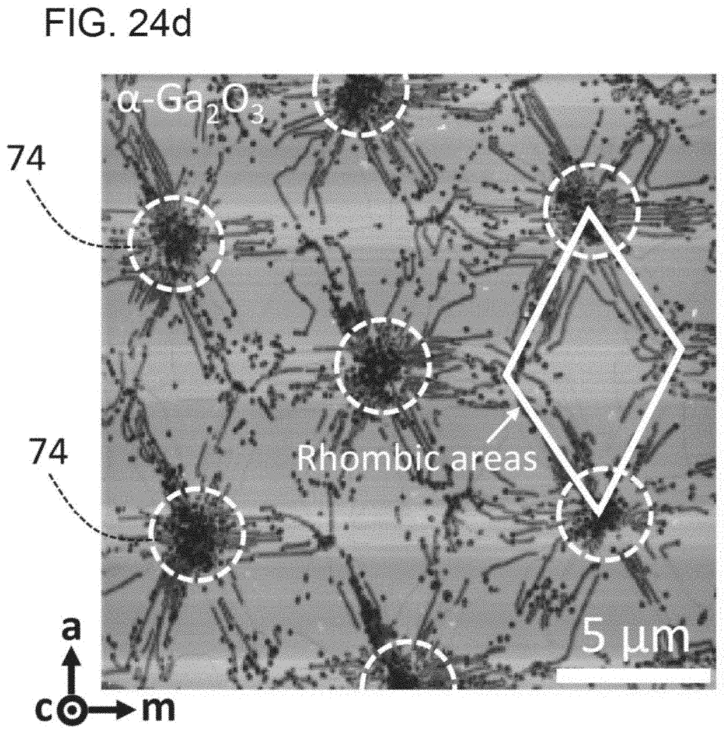

A mask layer (a thickness of 50 nm) was formed as with Example 1 by using a sapphire substrate (a c-plane, an off-angle of 0.25 degrees) having a surface on which an α-Ga₂O₃ layer was formed as the substrate. In Example 2, a plurality of openings (dot-like openings) (diameter: 3 μm) were formed. The mask layer was processed such that the plurality of openings were arranged on the substrate such that the distance from the center of each of the openings to the center of the nearest neighboring opening was 10 μm and the centers of openings were positioned in the vertices of a triangular lattice (an equilateral triangular lattice in the present example). In the present example, the centers of the plurality of openings provided in the mask layer were positioned in the vertices of the triangular lattice (the equilateral triangular lattice in present example) as illustrated in FIG. 24-b, and one edge of each triangular shape of the triangular lattice was arranged so as to be parallel to the a-axis direction as illustrated in FIG. 24-b. It was possible to control the shapes and sizes of the regions in which dislocation was reduced by disposing the centers of the openings in the mask in the vertices of the equilateral triangular lattice and arranging one edge of each triangular shape of the triangular lattice to be parallel to the axial direction as described above.

### 2. Formation of Crystal

A multilayer structure was obtained by causing the crystal to grow and be associated as with 2-1. to 2-3. of Example 1 described above.

### 2-4. Evaluation

Regarding the obtained multilayer structure, atomic force microscope (AFM) observation was performed after surface polishing and washing. The result is shown in FIG. 24-c. An explanatory view showing the positions in which the openings are provided in the mask in planar view on the AFM image shown in FIG. 24-c by dotted lines is shown in FIG.-d. As it is clear from FIG. 24-c and FIG. 24-d, an anisotropy in which dislocation does not extend in the a-axis direction and dislocation extends in the m-axis direction was found. As shown in FIG. 24-d, it is understood that the dislocation was reduced in a region on the inside of a rhombus as compared to regions around the vertices of the rhombus. The long edge of diagonal lines of the rhombus matched with the a-axis direction. It was also found that the dislocation in the c-axis direction was also reduced in accordance with the growth of the crystal because the dislocation in the m-axis direction extended.

### EXAMPLE 3

### 1. Formation of ELO Mask

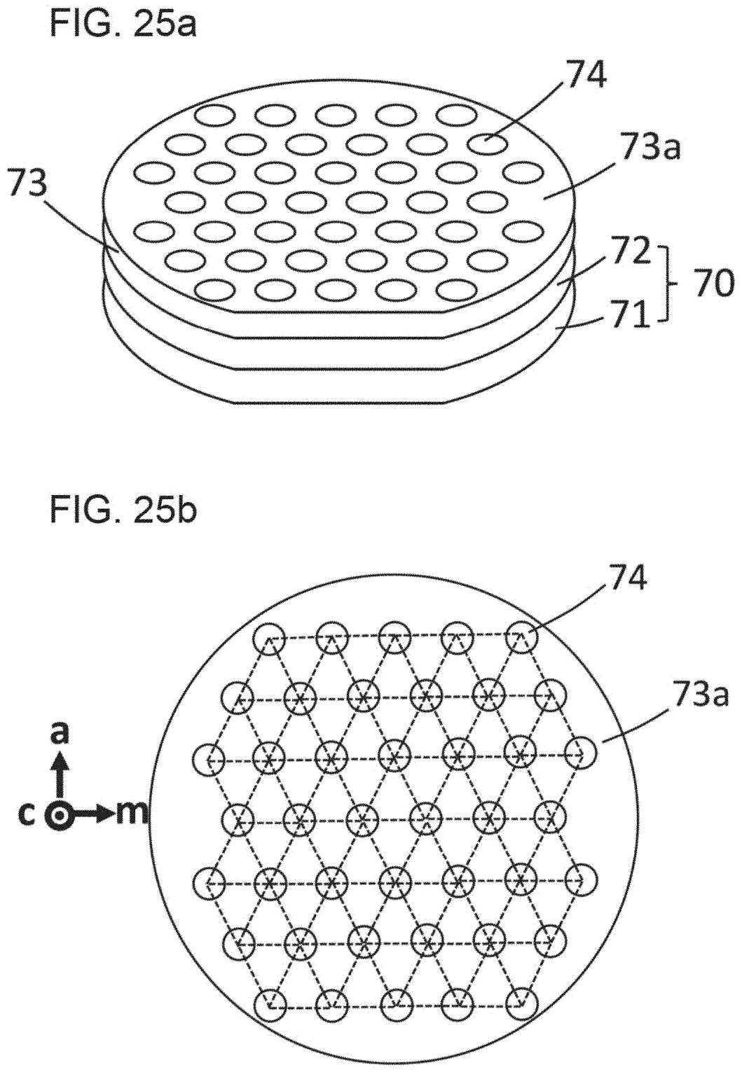

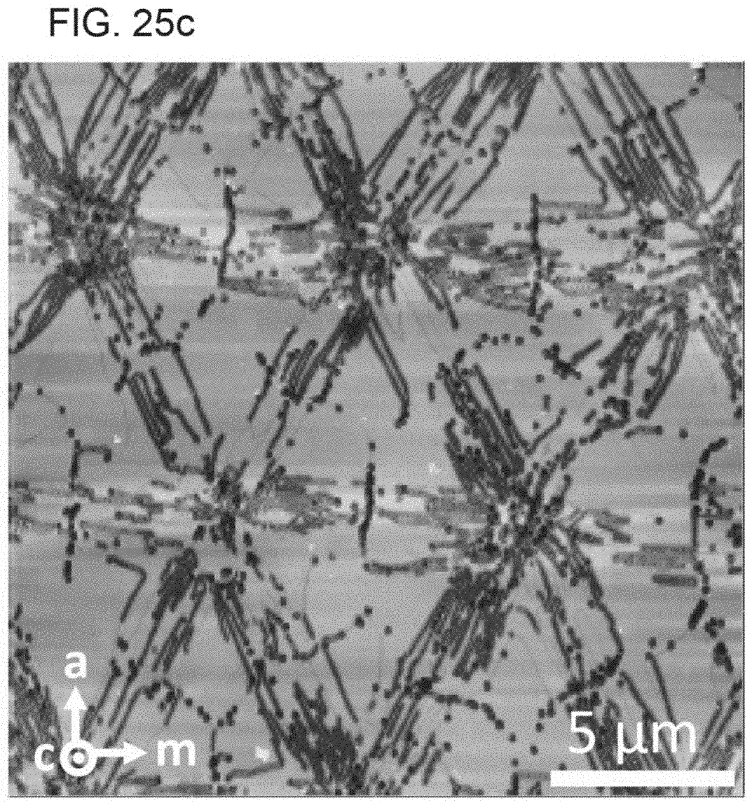

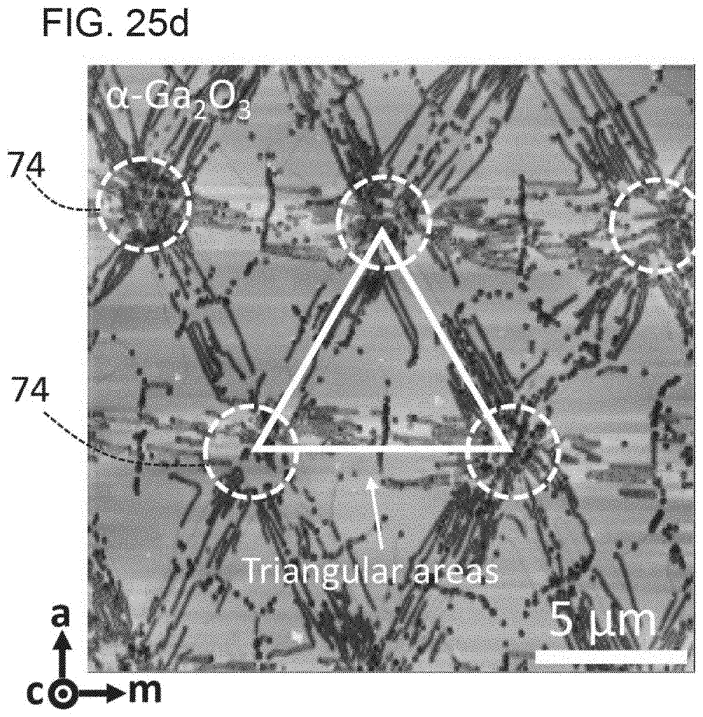

A mask layer (a thickness of 50 nm) was formed as with Example 1 and 2 by using a sapphire substrate (a c-plane, an off-angle of 0.25 degrees) having a surface on which an α-Ga₂O₃ layer was formed as the substrate and using spattering on the substrate. In Example 3, a plurality of openings (dot-like openings) (diameter: 3 μm) were formed. The mask layer was processed such that the plurality of openings were arranged on the substrate such that the distance from the center of each of the openings to the center of the nearest neighboring opening was 10 μm and the centers of openings were positioned in the vertices of a triangular lattice (an equilateral triangular lattice in the present example). In the present example, the centers of the plurality of openings provided in the mask layer were positioned in the vertices of the triangular lattice, and one edge of each triangular shape of the triangular lattice was arranged so as to be parallel to the m-axis direction as shown in FIG. 25-b.

### 2. Formation of Crystal

A multilayer structure was obtained by causing the crystal to grow and be associated as with 2-1. to 2-3. of Example 1 described above.

### 2-4. Evaluation

Regarding the obtained multilayer structure, atomic force microscope (AFM) observation was performed after surface polishing and washing. The result is shown in FIG. 25-c. An explanatory view showing the positions in which the openings are provided in the mask in planar view on the AFM image shown in FIG. 25-c by dotted lines is shown in FIG. 20-d. As it is clear from FIG. 25-c and FIG. 25-d, an anisotropy in which dislocation does not extend in the a-axis direction and dislocation extends in the m-axis direction was found. As shown in FIG. 25-d, triangular areas in which dislocation is reduced were obtained. The vertices of the triangular shapes overlapped with the centers of the openings in the mask layer in planar view, and it is understood that the dislocation was reduced in the inner regions of the triangular shapes as compared to the regions around the vertices of the triangular shapes. It was also found that the dislocation in the c-axis direction was also reduced because the dislocation in the m-axis direction extended. It was possible to control the shapes and sizes of the regions in which dislocation of the crystal was reduced by disposing the dot-like openings in the mask on vertices of the equilateral triangle shapes of the triangular lattice and arranging one edge of each of the equilateral triangle shapes to be parallel to the axial direction as described above.

According to the embodiment of the present disclosure, it becomes possible to obtain the gallium-oxide semiconductor crystal having a region in which dislocation is reduced mainly in the a-axis direction. As above, it becomes possible to obtain the wide-range semiconductor crystal in which dislocation is reduced.

### INDUSTRIAL APPLICABILITY

The semiconductor device in the embodiment of the present disclosure is usable in any field such as semiconductors (for example, compound semiconductor electronic devices), electronic components, electromechanical components, optical and electronic photography related apparatuses, and industrial components, but is particularly suitable for use in a power device and the like.

The embodiments of the present invention are exemplified in all respects, and the scope of the present invention includes all modifications within the meaning and scope equivalent to the scope of claims.

### REFERENCE SIGNS LIST

1a First semiconductor region
1b Second semiconductor region
2 Semiconductor layer
2a Inverted channel region
2b Oxide film
4a Insulating film
4b Insulating film
5a Third electrode
5b First electrode
5c Second electrode
9 Substrate
19 Film formation apparatus
20 Substrate
21 Susceptor
22a Carrier gas supply source
22b Carrier gas (diluted) supply source
23a Flow rate regulation valve for carrier gas
23b Flow rate regulation valve for carrier gas (diluted)
24 Mist generation source
24a Raw material solution
24b Atomization droplet
25 Container
25a Water
26 Ultrasonic transducer
27 Supply pipe
28 Hotplate (heater)
29 Exhaust port
30 Film formation chamber
50 Hydride vapor phase epitaxy (HVPE) apparatus
51 Reaction chamber
52a Heater
52b Heater
53a Halide-containing-raw-material-gas supply source
53b Metal-containing-raw-material-gas (metal-halide-gas) supply pipe
54a Reactive-gas supply source
54b Reactive-gas supply pipe
55a Oxygen-containing-raw-material-gas supply source
55b Oxygen-containing-raw-material-gas supply pipe
56 Substrate holder
57 Metal source
58 Protective sheet
59 Gas discharge portion
70 Substrate (crystal substrate)
71 Sapphire substrate
72 Gallium oxide layer
73 Mask layer
74 Opening that passes through mask layer
100 Semiconductor device
100a First plane side
120 Semiconductor device
120a First plane side
120b Second plane side
121 Semiconductor layer
121a First semiconductor layer
121b Second semiconductor layer
125a Schottky electrode
125b Ohmic electrode
131a n−-type semiconductor layer
131b First n+-type semiconductor layer
131c Second n+-type semiconductor layer
132 p-type semiconductor layer
132a p+-type semiconductor layer
134 Gate insulating film
135a Gate electrode
135b Source electrode
135c Drain electrode
139 Substrate
140 Semiconductor device
140a First plane side of semiconductor layer
140b Second plane side of semiconductor layer
141 Semiconductor layer
141a First semiconductor layer
141b Second semiconductor layer
141c Third semiconductor layer
143 Trench
145a Third electrode
145b First electrode
145c Second electrode
150 Semiconductor device
150a First plane side of semiconductor layer
150b Second plane side of semiconductor layer
151a First semiconductor layer
151 Second semiconductor layer
152a p-type semiconductor region
152b Third semiconductor layer
153 Semiconductor layer
154 Gate insulating film
155a Gate electrode
160 Semiconductor device
161 Barrier height adjustment region
162 First electrode
163 Semiconductor layer
164 Second electrode
165 Guard ring
166 Trench
170 Power source system
171 Power source apparatus
172 Power source apparatus
173 Control circuit
180 System apparatus
181 Electronic circuit
182 Power source system
192 Inverter
193 Transformer
194 Rectification MOSFET
195 DCL
196 PWM control circuit
197 Voltage comparator
200 Semiconductor device
200a First plane side
200b Second plane side
201 Both-plane-cooling-type power card
202 Refrigerant tube
203 Spacer
208 Insulating plate (insulating spacer)
209 Sealing resin portion
221 Dividing wall
222 Flow path
300 Semiconductor device
300a First plane side
300b Second plane side
301a Semiconductor chip
302b Metal heat transfer plate (protruding terminal portion)
303 Heat sink and electrode
303b Metal heat transfer plate (protruding terminal portion)
304 Solder layer
305 Control electrode terminal
308 Bonding wire
400a Pitch
401 Substrate (crystal substrate)
401a Surface of substrate
402a Protruding portion
402b Depressed portion
404 Mask layer
405 Inclined plane

What is claimed is:

1. A semiconductor device, comprising at least:
a semiconductor layer; and
a gate electrode that is arranged directly or via another layer on the semiconductor layer,
the semiconductor device being configured such a manner as to cause a current to flow in the semiconductor layer at least in a first direction that is along with an interface between the semiconductor layer and the gate electrode,
the semiconductor layer having a corundum structure,
a direction of an m-axis in the semiconductor layer being the first direction.

2. A semiconductor device, comprising at least:
a semiconductor layer having a corundum structure;
a first electrode disposed on a first plane side of the semiconductor layer; and
a second electrode disposed on a second plane side that is a side opposite from the first plane side,
the first plane being an m-plane,
the second electrode being longer than the first electrode in at least a first direction, and
the first direction being a c-axis direction of the semiconductor layer.

3. The semiconductor device according to claim 1, wherein the semiconductor layer includes a metal oxide containing at least one metal selected from gallium, indium, rhodium, iridium, and aluminum.

4. The semiconductor device according to claim 1, wherein a major component of the semiconductor layer is a metal oxide containing at least gallium.

5. The semiconductor device according to claim 1, wherein the semiconductor layer has a carrier concentration of 1×10¹⁹/cm³ or less.

6. The semiconductor device according to claim 2, wherein the first plane is a c-plane.

7. The semiconductor device according to claim 1, wherein the semiconductor layer includes at least a dislocation that extends in the first direction.

8. The semiconductor device according to claim 1, wherein the semiconductor layer does not substantially include a dislocation that extends in a direction that is vertical or substantially vertical to the first direction.

9. The semiconductor device according to claim 1, wherein the semiconductor device is a power device.

10. The semiconductor device according to claim 9, wherein the semiconductor device is a power module, an inverter, or a converter.

11. The semiconductor device according to claim 9, wherein the semiconductor device is a power card.

12. The semiconductor device according to claim 10, further comprising a cooler and an insulation member, wherein the cooler is provided on each of both sides of the semiconductor layer via at least the insulation member.

13. The semiconductor device according to claim 11, wherein:
a heat release layer is provided on each of both sides of the semiconductor layer; and
the cooler is provided on an outer side of the heat release layer via at least the insulation member.

14. A semiconductor system, comprising a semiconductor device, wherein the semiconductor device is the semiconductor device according to claim 1.

15. A crystal growth method, comprising causing crystal growth of crystal having a corundum structure on a c-plane of a crystal substrate for crystal growth having a corundum structure, the crystal substrate having an uneven portion provided thereon such that a dislocation in accordance with the crystal growth further extends in an m-axis direction than in an a-axis direction.

16. The method according to claim 15, wherein the crystal contains metal oxide containing at least one metal selected from gallium, indium, rhodium, iridium, and aluminum.

17. The method according to claim 15, wherein a major component of the crystal is metal oxide containing at least gallium.

18. The method according to claim 15, wherein the uneven portion includes at least two or more of inclined planes that are m-planes adjacent to each other.

19. The method according to claim 15, wherein the uneven portion includes at least two or more of inclined planes that are m-planes facing each other.
